(19) United States
(12) Patent Application Publication
(10) Pub. No.: US 2024/0421022 A1
(43) Pub. Date: Dec. 19, 2024

(54) SEMICONDUCTOR DEVICE

(71) Applicant: Rohm Co., Ltd., Kyoto-shi (JP)

(72) Inventors: Hirokatsu UMEGAMI, Kyoto-shi (JP); Kazunori FUJI, Kyoto-shi (JP)

(21) Appl. No.: 18/816,494

(22) Filed: Aug. 27, 2024

Related U.S. Application Data
(63) Continuation of application No. PCT/JP2023/005441, filed on Feb. 16, 2023.

(30) Foreign Application Priority Data
Mar. 2, 2022 (JP) 2022-032071
Mar. 24, 2022 (JP) 2022-049004

(51) Int. Cl. H01L 23/34; H01L 23/00; H01L 23/31; H01L 23/495

(52) U.S. Cl. CPC H01L 23/34; H01L 23/3107; H01L 23/49562; H01L 24/48; H01L 24/49; H01L 2224/48247; H01L 2224/48465; H01L 2224/4903; H01L 2224/49505; H01L 2924/13091

(57) ABSTRACT

A semiconductor device includes a first lead, a second lead, a third lead, a semiconductor element mounted on the third lead, a first wire, and a second wire. The first lead includes a first pad portion, and a first terminal for measuring a temperature. The second lead includes a second pad portion, and a second terminal portion for measuring a temperature. The semiconductor element includes an element obverse surface, and a first electrode arranged on the element obverse surface. The first wire and the second wire are made of metals having different thermoelectric powers. The first wire is connected to the first electrode and the first pad portion. The second wire is connected to the first electrode and the second pad portion.

### TECHNICAL FIELD

The present disclosure relates to a semiconductor device.

### BACKGROUND ART

Various configurations have been proposed for a semiconductor device including a semiconductor element. JP-discloses an example of a conventional A-2019-121745 semiconductor device. The semiconductor device disclosed in this document includes a semiconductor element, a plurality of leads, and a sealing resin. The semiconductor element is supported by a lead (a die pad). The sealing resin covers a portion of each lead and the semiconductor element. Each lead has a terminal portion. In the semiconductor device described in JP-A-2019-121745, the semiconductor element is a switching element and includes three terminal portions for mounting.

In a semiconductor device such as the one disclosed in JP-A-2019-121745, it is to necessary determine the temperature of a semiconductor element because the presence/absence of a failure, life, and reliability are closely related to the temperature during operation. In the case where the semiconductor device is a module product, a temperature sensor such as a diode sensor or a thermistor may be provided inside. However, if the semiconductor device is a discrete component, the mounting area is limited and it is difficult to allocate the space for the temperature sensor. The semiconductor device described in JP-A-2019-212930 includes a temperature detection element formed within a power transistor formation area near a pad of a transistor. Since the temperature detection element is formed in the power transistor formation area, the temperature of a semiconductor element can be accurately detected. However, the formation of the temperature detection element reduces the space for an intended use in an active area.

### BRIEF DESCRIPTION OF THE DRAWINGS

FIG. 1 is a perspective view showing a semiconductor device according to a first embodiment (a first aspect) of the present disclosure.

FIG. 2 is a plan view (seen through a sealing resin) showing the semiconductor device of FIG. 1.

FIG. 3 is a cross-sectional view along line III-III in

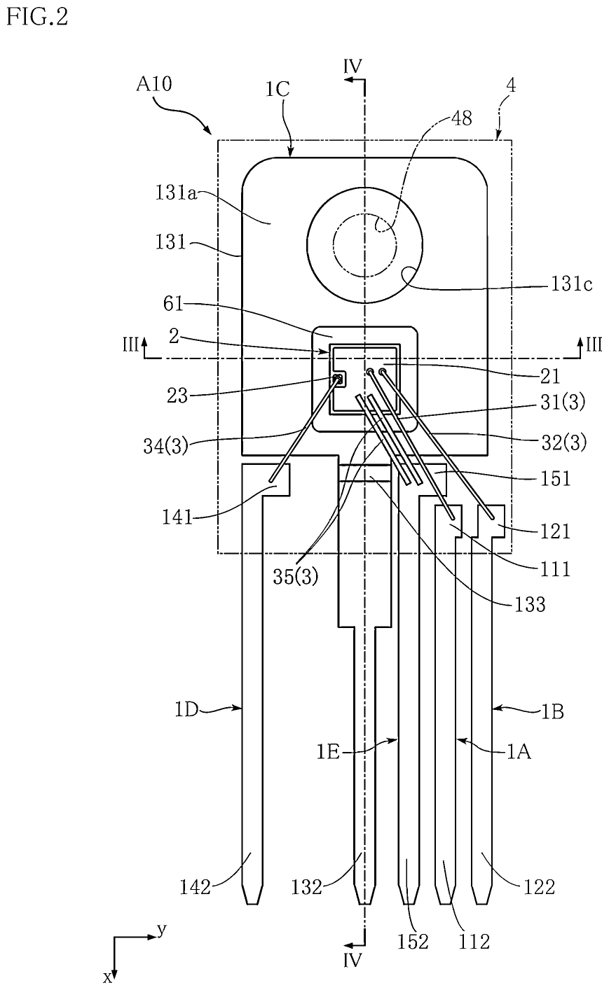

FIG. 2.

FIG. 4 is a cross-sectional view along line IV-IV in FIG. 2.

FIG. 5 is a plan view (seen through a sealing resin) showing a semiconductor device according to a first variation of the first embodiment (the first aspect).

FIG. 6 is a plan view (seen through a sealing resin) showing a semiconductor device according to a second variation of the first embodiment (the first aspect).

FIG. 7 is a plan view (seen through a sealing resin) showing a semiconductor device according to a third variation of the first embodiment (the first aspect).

FIG. 8 is a perspective view showing a semiconductor device according to a second embodiment (a first aspect) of the present disclosure.

FIG. 9 is a plan view (seen through a sealing resin) showing the semiconductor device of FIG. 8.

FIG. 10 is a cross-sectional view along line X-X in FIG. 9.

FIG. 11 is a cross-sectional view along line XI-XI in FIG. 9.

FIG. 12 is a cross-sectional view along line XII-XII in FIG. 9.

FIG. 13 is a cross-sectional view along line XIII-XIII in FIG. 9.

FIG. 14 is a plan view (seen through a sealing resin) showing a semiconductor device according to a variation of the second embodiment (the first aspect).

FIG. 15 is a perspective view showing a semiconductor device according to a third embodiment (the first aspect) of the present disclosure.

FIG. 16 is a perspective view showing the semiconductor device of FIG. 15, with a bottom surface thereof facing upward.

FIG. 17 is a plan view (seen through a sealing resin) showing the semiconductor device of FIG. 15.

FIG. 18 is a bottom view showing the semiconductor device of FIG. 15.

FIG. 19 is a cross-sectional view along line XIX-XIX in FIG. 17.

FIG. 20 is a cross-sectional view along line XX-XX in FIG. 17.

FIG. 21 is a perspective view showing a semiconductor device according to a first embodiment (a second aspect) of the present disclosure.

FIG. 22 is a plan view showing the semiconductor device of FIG. 21, as seen through a sealing member.

FIG. 23 is a bottom view showing the semiconductor device of FIG. 21.

FIG. 24 is a cross-sectional view along line XXIV-XXIV in FIG. 22.

FIG. 25 is a perspective view showing a semiconductor module including the semiconductor device of FIG. 21.

FIG. 26 is a plan view showing the semiconductor module of FIG. 25, as seen through a resin member.

FIG. 27 is a partially enlarged view showing a part of FIG. 26.

FIG. 28 is a cross-sectional view along line XXVIII-XXVIII in FIG. 26.

FIG. 29 is a cross-sectional view along line XXIX-XXIX in FIG. 26.

FIG. 30 is a cross-sectional view showing a semiconductor device according to a first variation of the first embodiment (the second aspect).

FIG. 31 is a cross-sectional view showing a semiconductor device according to a second variation of the first embodiment (the second aspect).

FIG. 32 is a cross-sectional view showing a semiconductor device according to a third variation of the first embodiment (the second aspect).

FIG. 33 is a cross-sectional view showing a semiconductor device according to a fourth variation of the first embodiment (the second aspect).

FIG. 34 is a cross-sectional view showing a semiconductor device according to a fifth variation of the first embodiment (the second aspect).

FIG. 35 is a cross-sectional view showing a semiconductor device according to a sixth variation of the first embodiment (the second aspect).

FIG. 36 is a plan view showing a semiconductor device according to a seventh variation of the first embodiment (the second aspect), as seen through a sealing member.

FIG. 37 is a cross-sectional view along line XXXVII-XXXVII in FIG. 36.

FIG. 38 is a cross-sectional view showing a semiconductor device according to a second embodiment (the second aspect) of the present disclosure.

FIG. 39 is a cross-sectional view showing a semiconductor device according to a third embodiment (the second aspect) of the present disclosure.

FIG. 40 is a plan view showing a first variation of the semiconductor module, as seen through a resin member.

FIG. 41 is a cross-sectional view along line XLI-XLI in FIG. 40.

FIG. 42 is a plan view showing a second variation of the semiconductor module, as seen through the resin member.

### DETAILED DESCRIPTION OF EMBODIMENTS

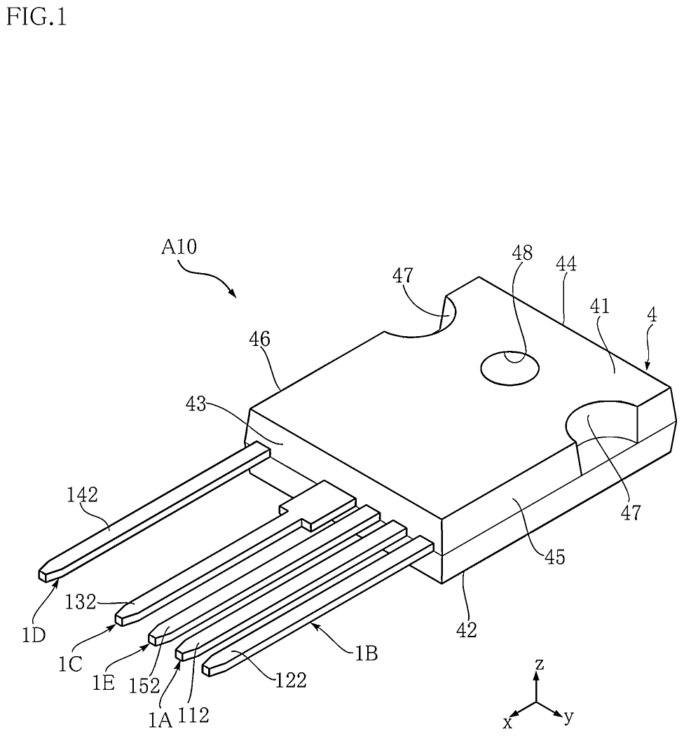

The following describes preferred embodiments of the present disclosure in detail with reference to the drawings. FIGS. 1 to 20 show embodiments according to a first aspect of the present disclosure, and FIGS. 21 to 42 show embodiments according to a second aspect of the present disclosure. The reference numerals used in FIGS. 1 to 20 are provided independently from the reference numerals used in FIGS. 21 to 42. Thus, the same reference numeral may be used for different members (or elements, etc.) pertaining to the first aspect and the second aspect, or different reference numerals may be used for identical (or similar) members pertaining to the first aspect and the second aspect.

The terms such as “first”, “second” and “third” in the present disclosure are used merely as labels, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”.

### First Embodiment (First Aspect)

The following describes a semiconductor device A10 according to a first embodiment (a first aspect) of the present disclosure, with reference to FIGS. 1 to 4. The semiconductor device A10 includes a first lead 1A, a second lead 1B, a third lead 1C, a fourth lead 1D, a fifth lead 1E, a semiconductor element 2, a plurality of wires 3, and a sealing resin 4.

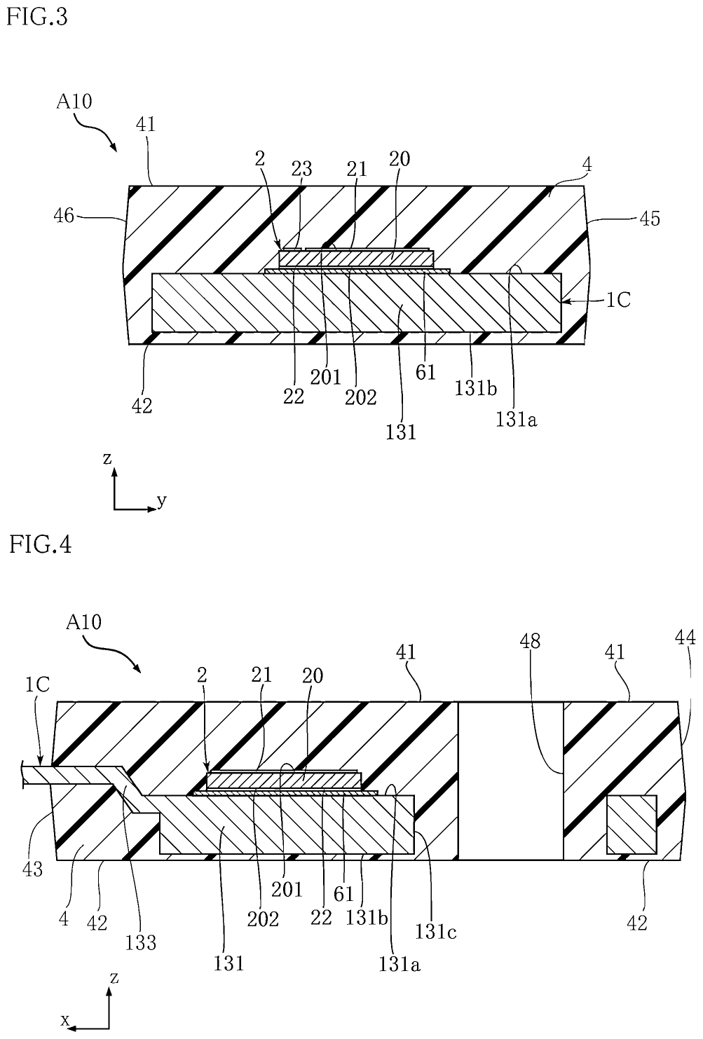

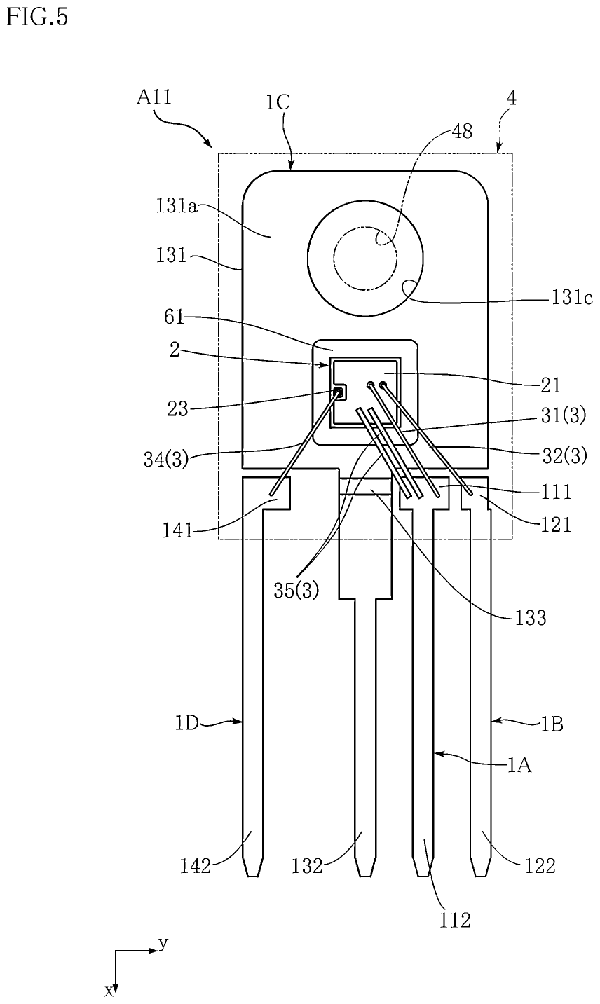

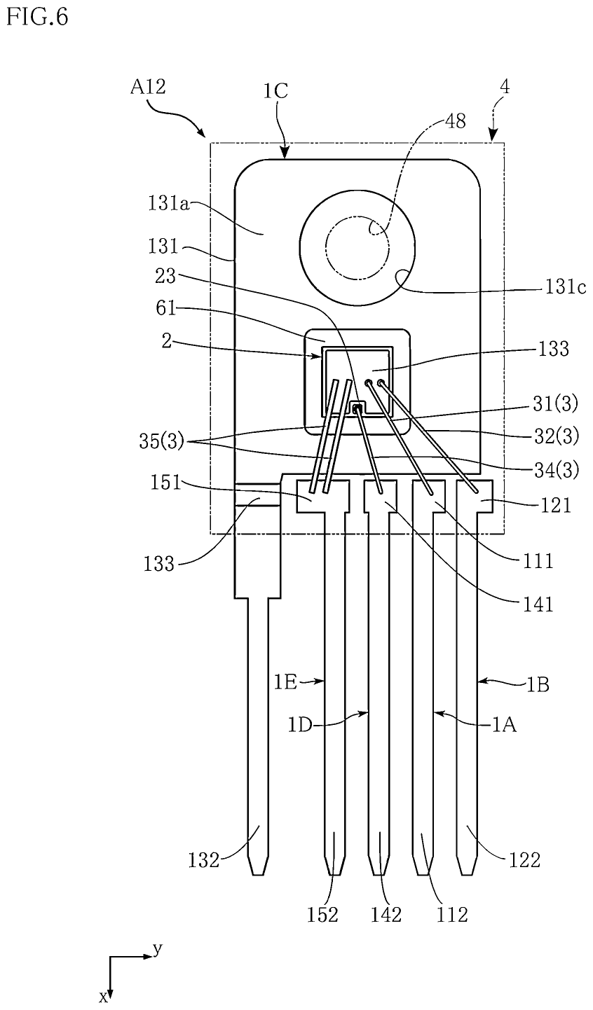

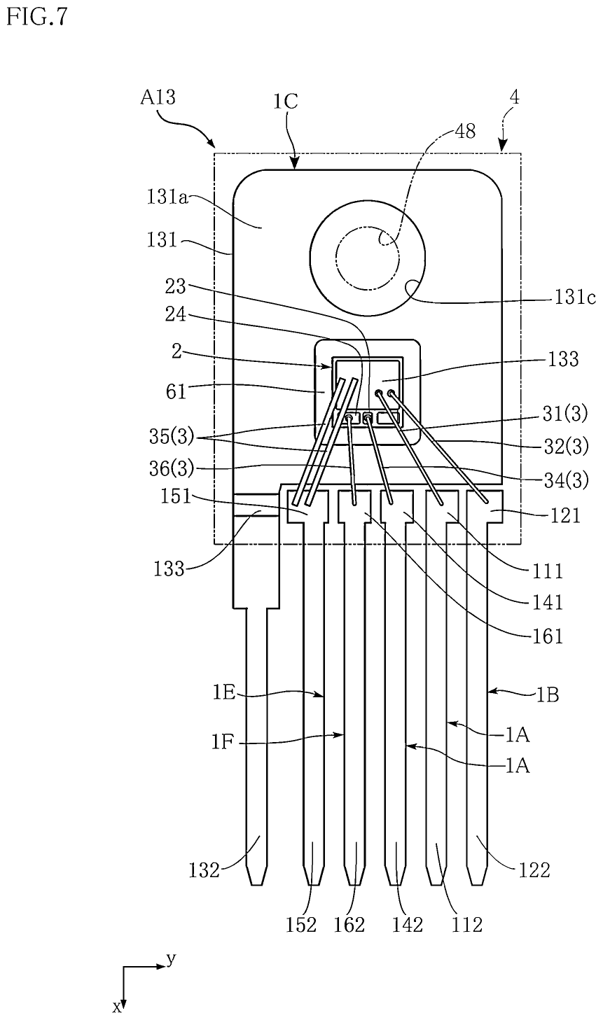

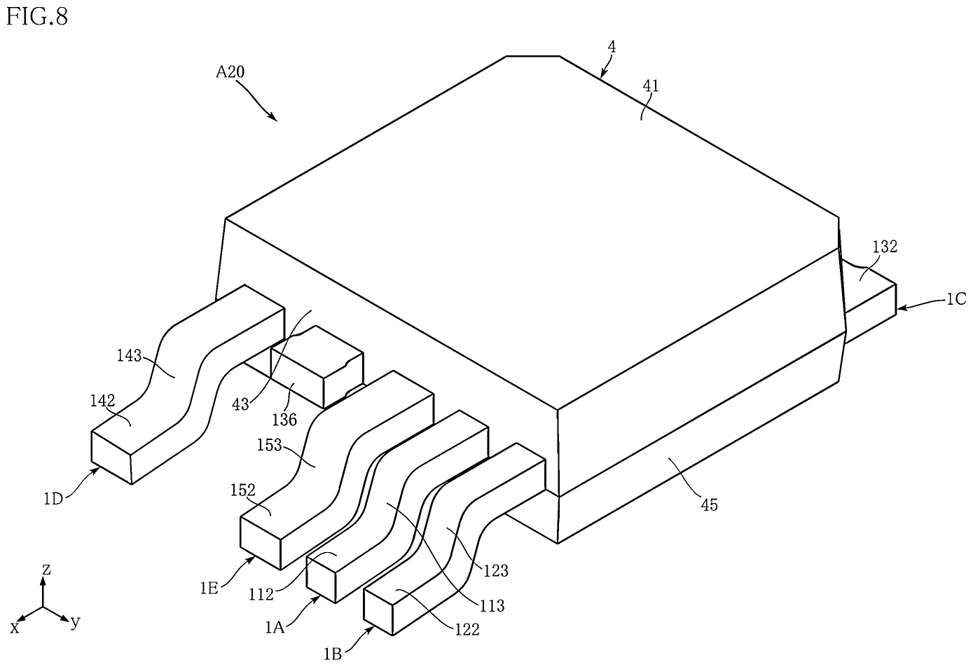

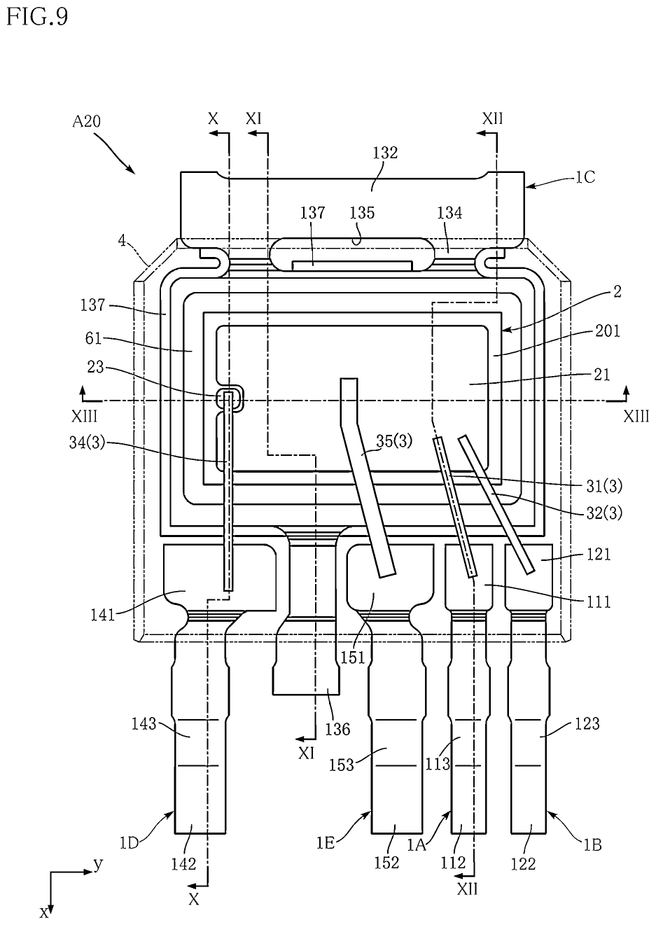

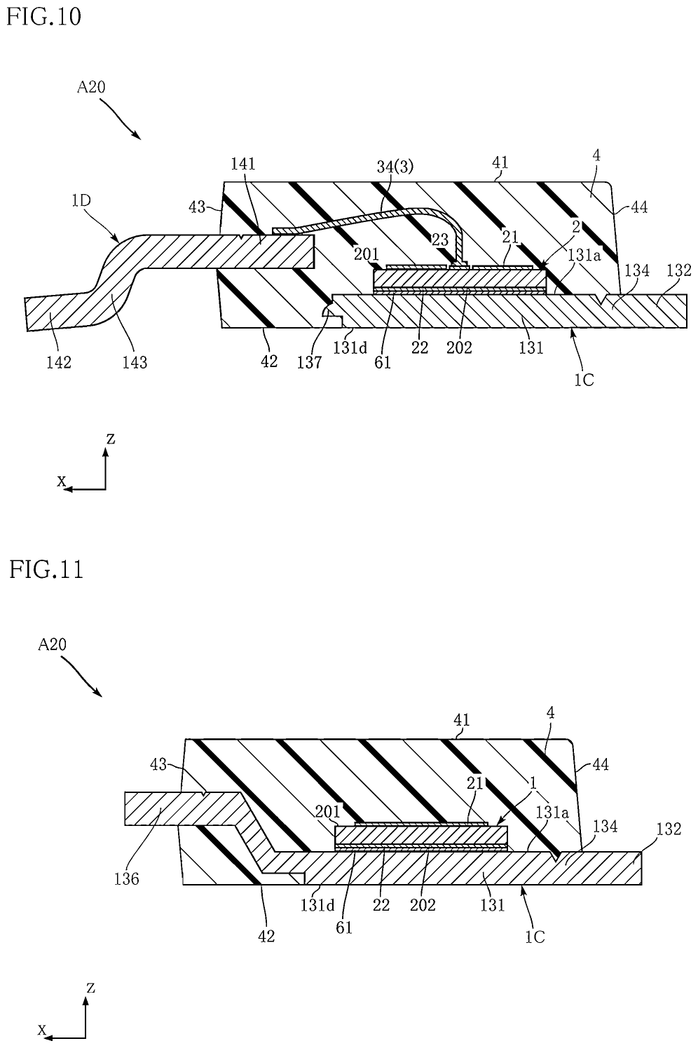

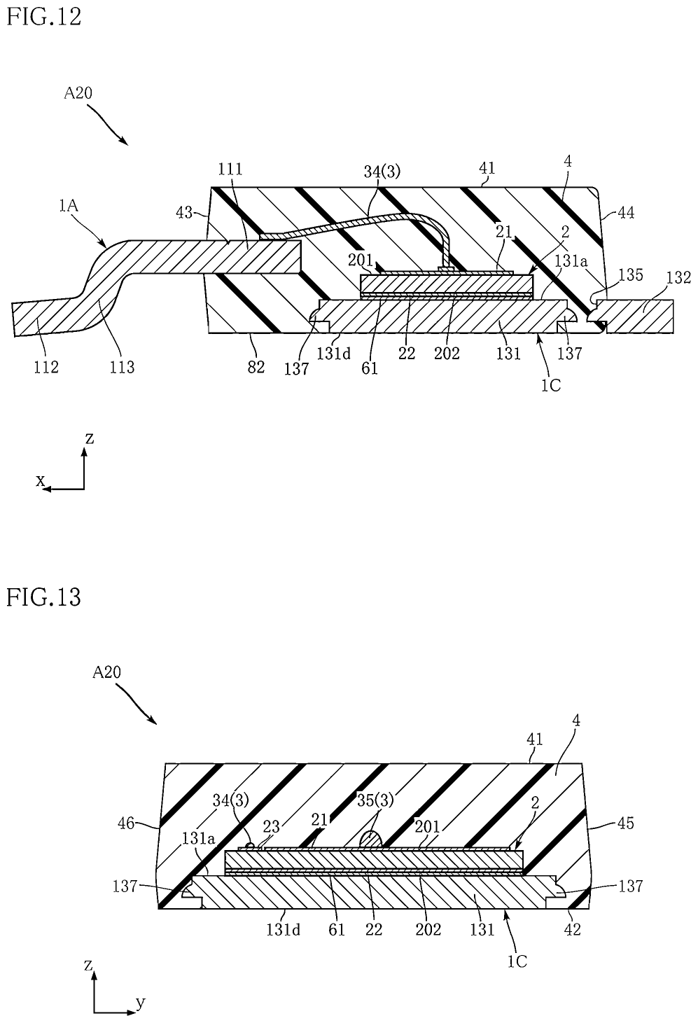

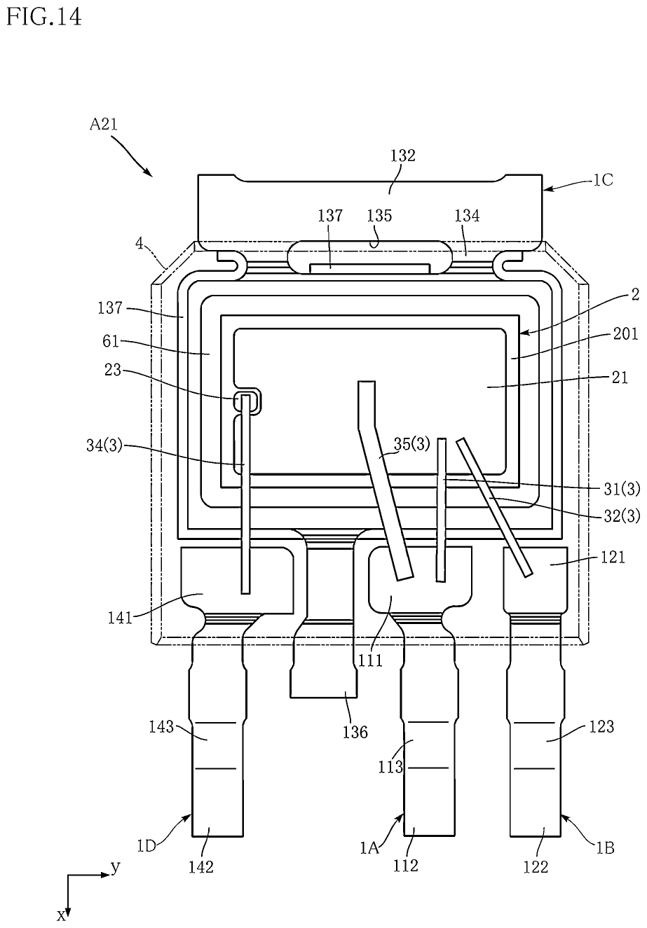

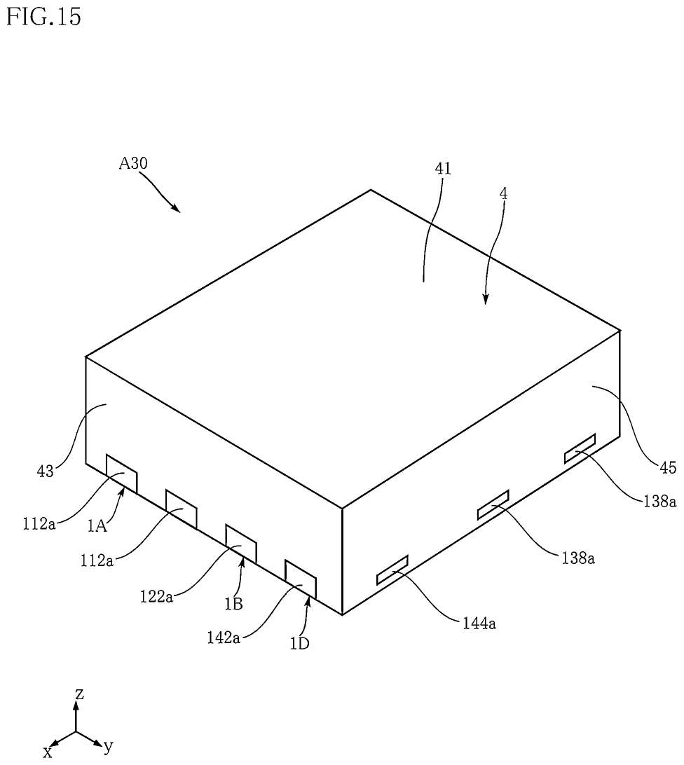

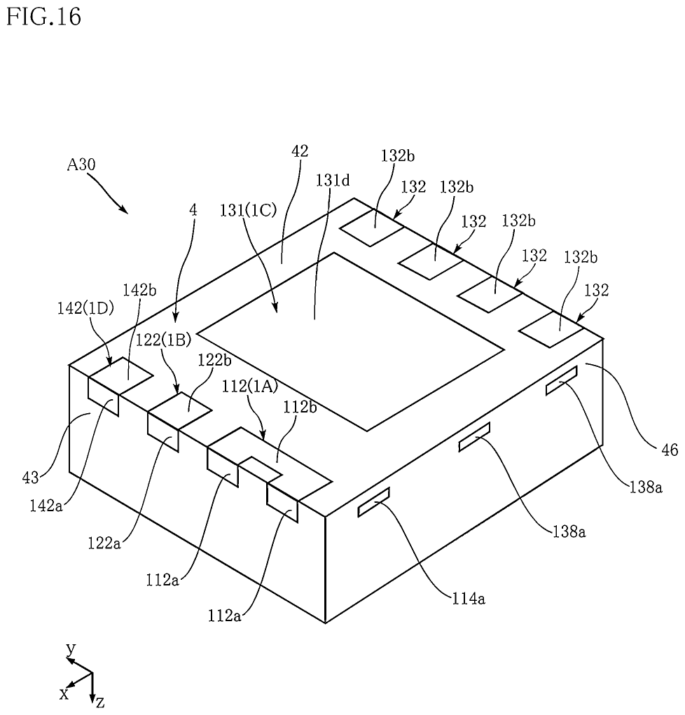

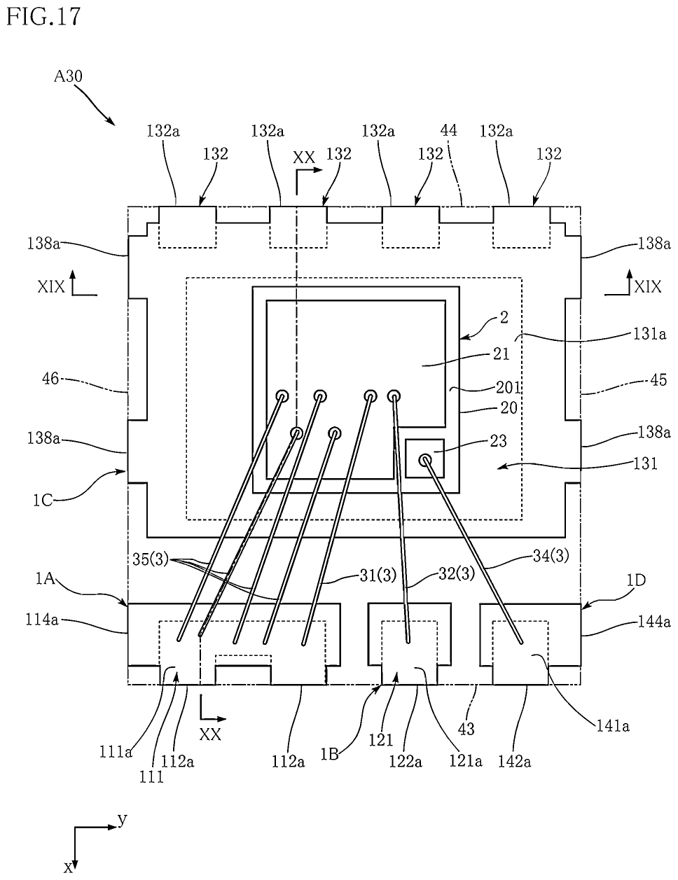

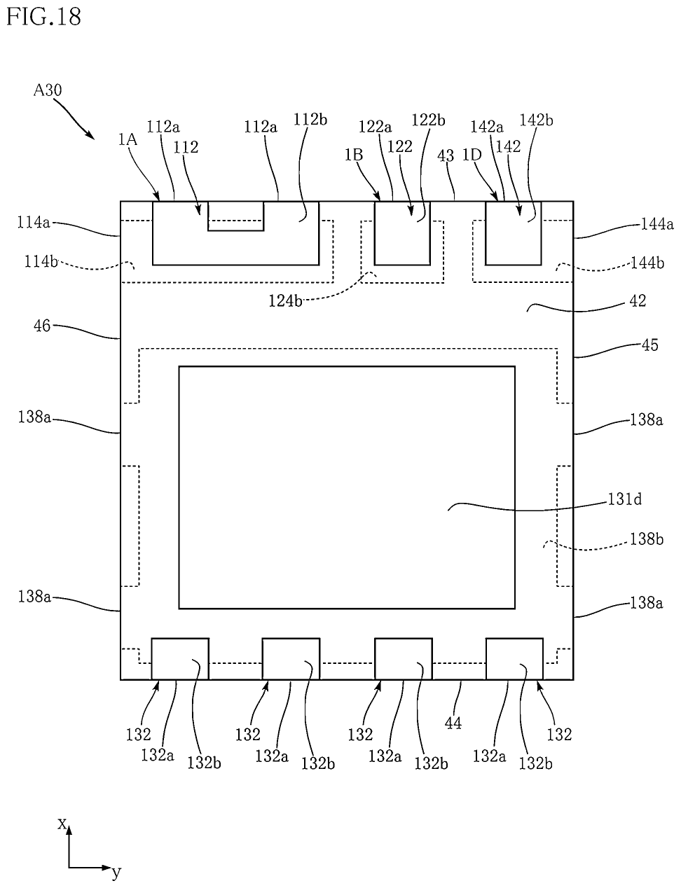

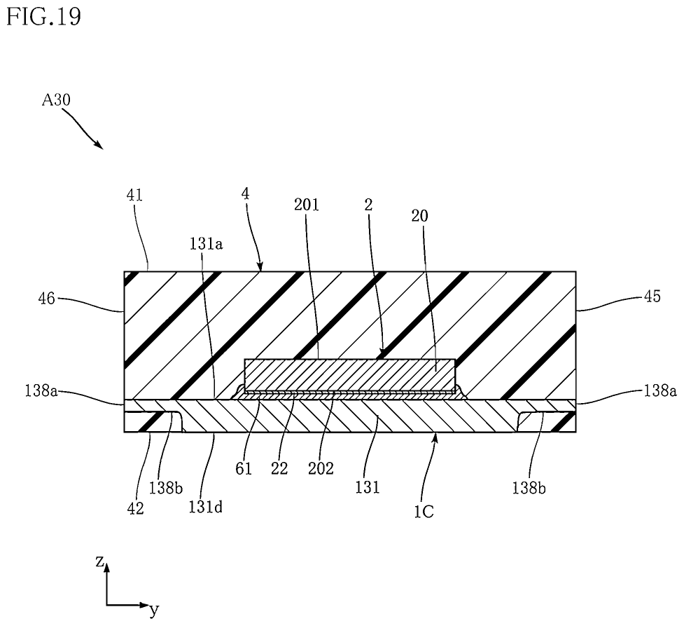

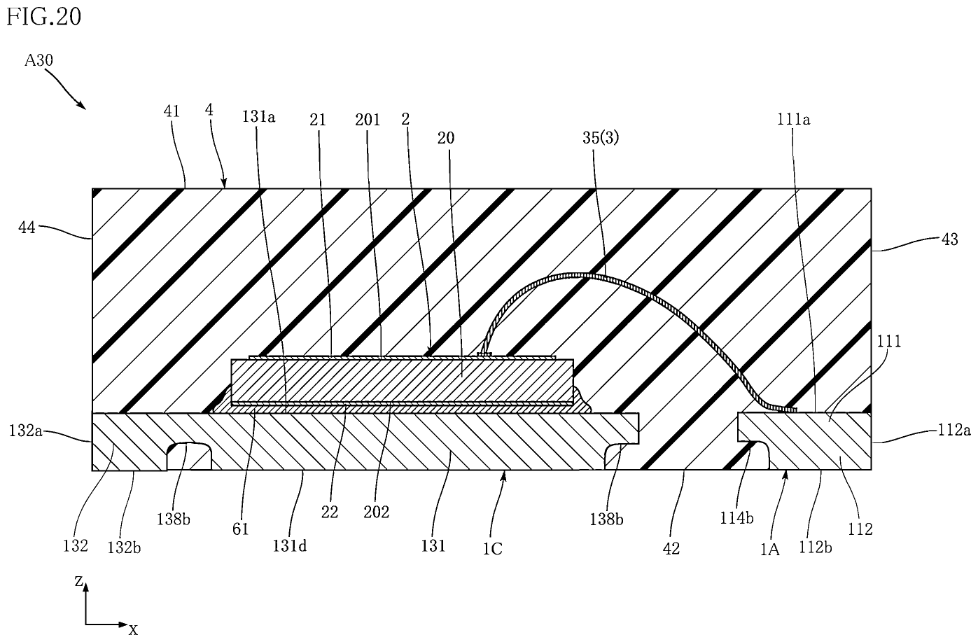

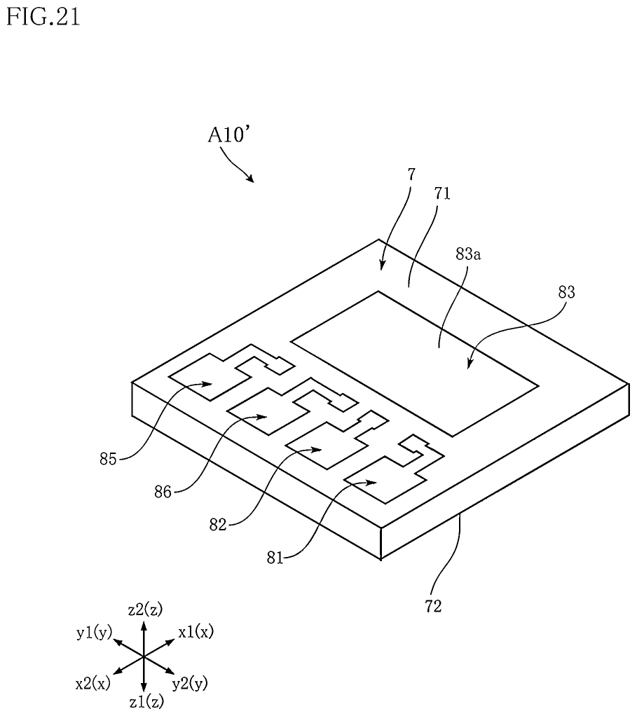

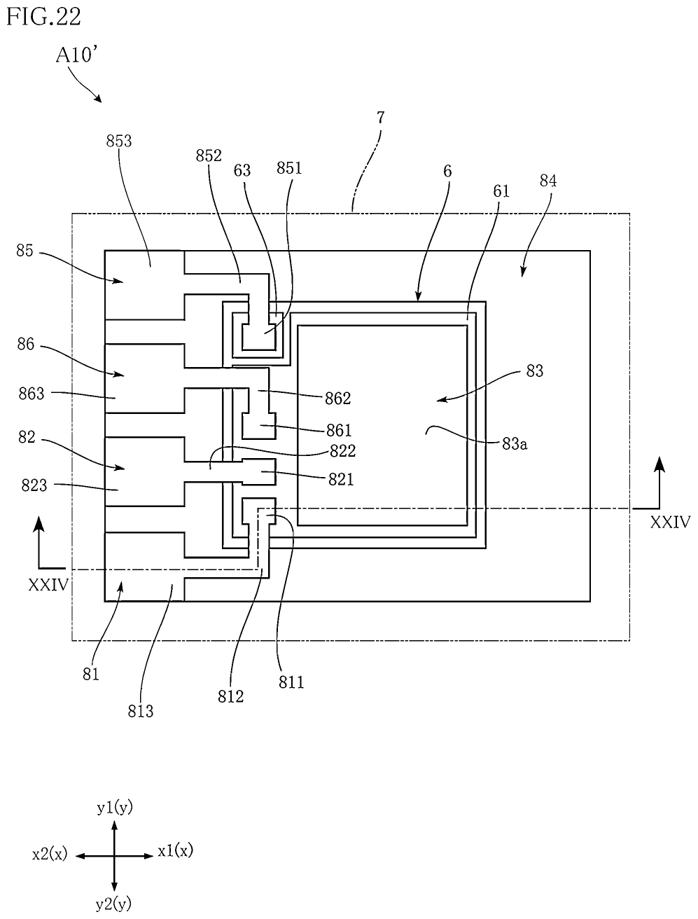

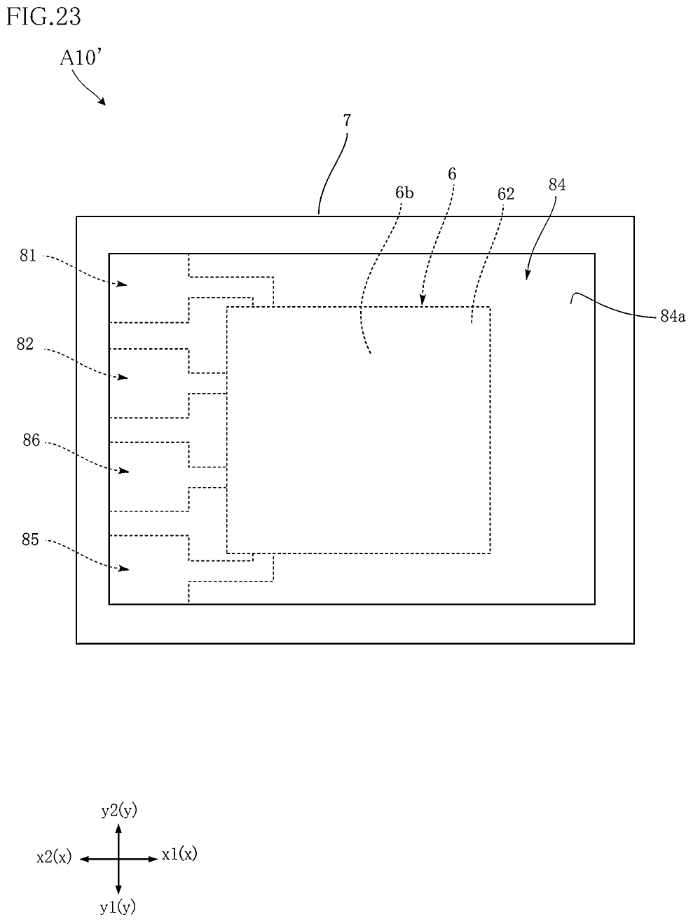

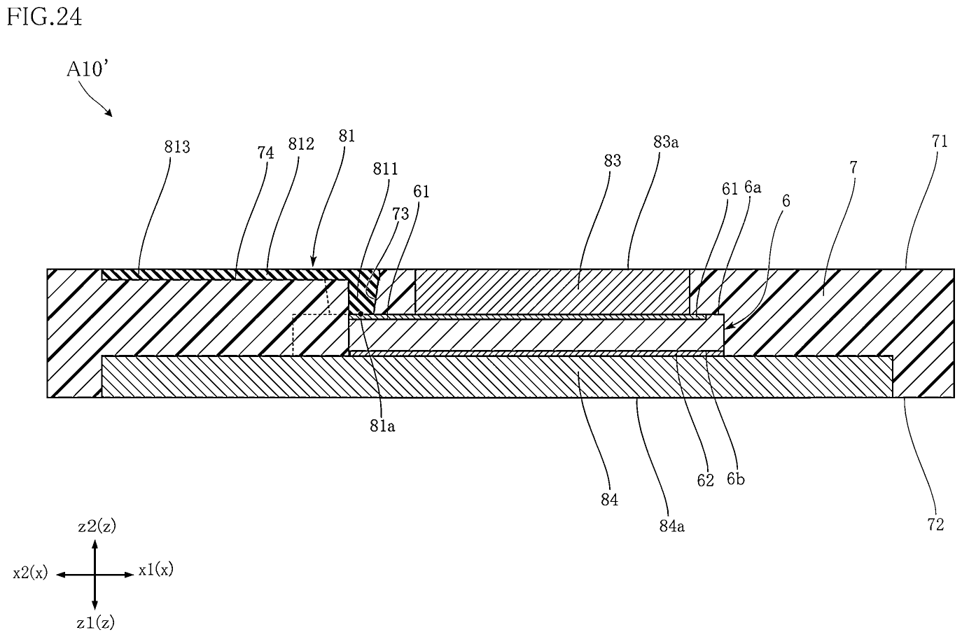

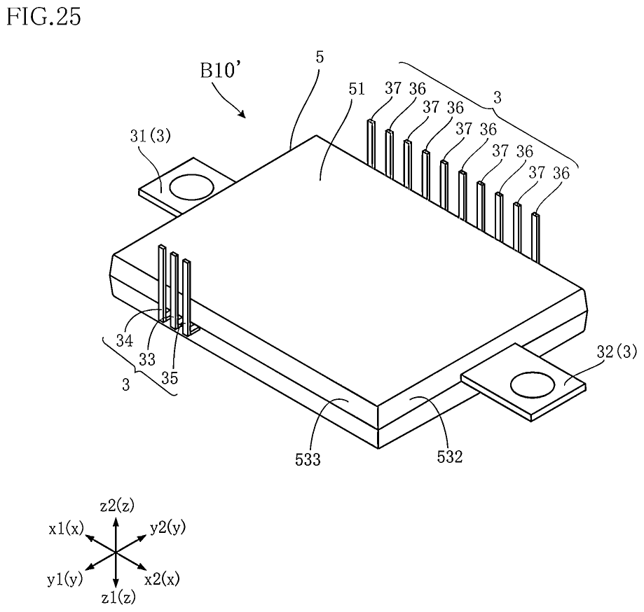

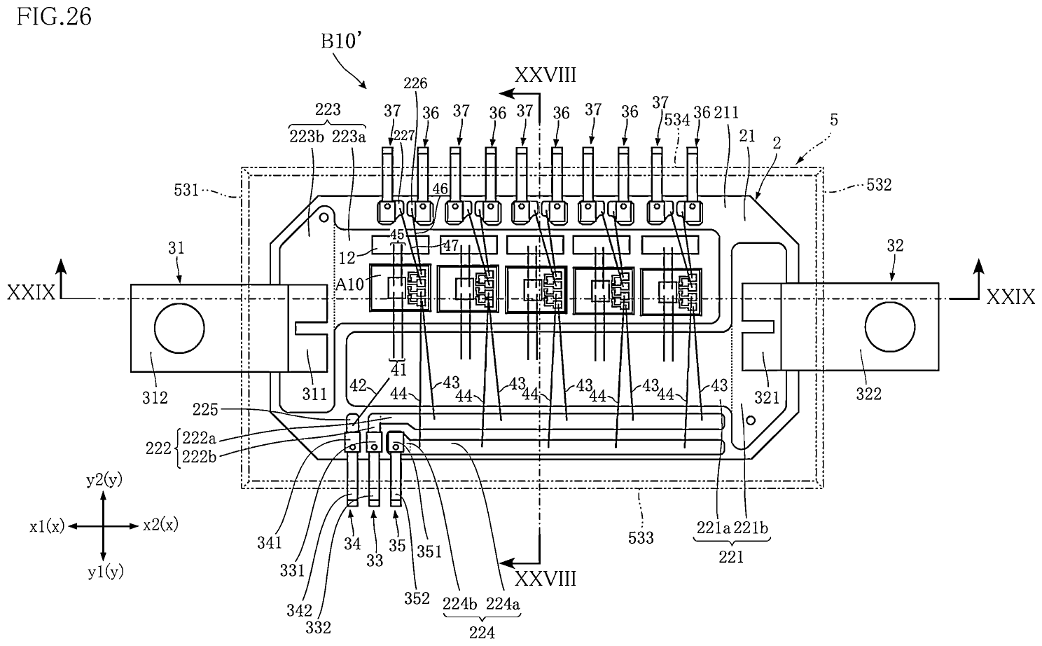

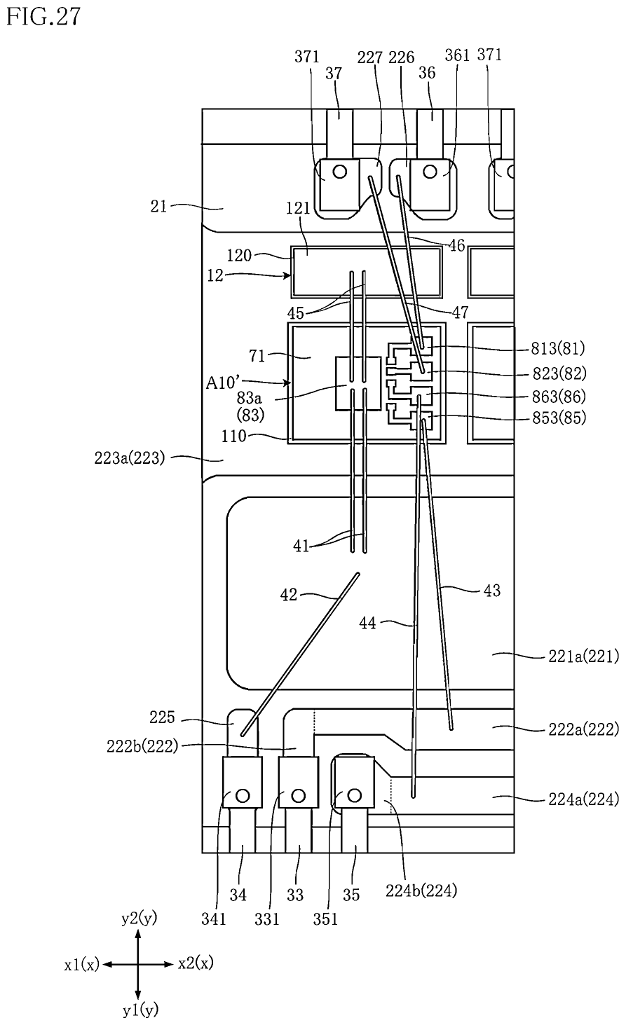

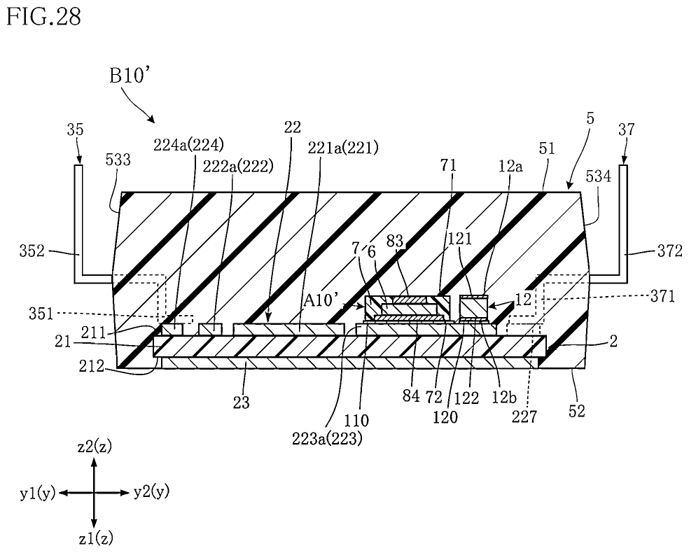

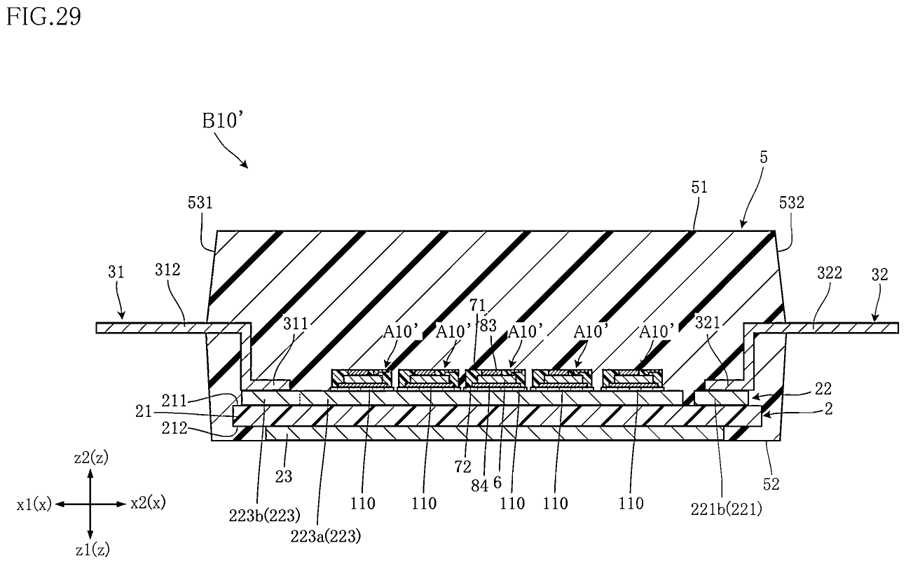

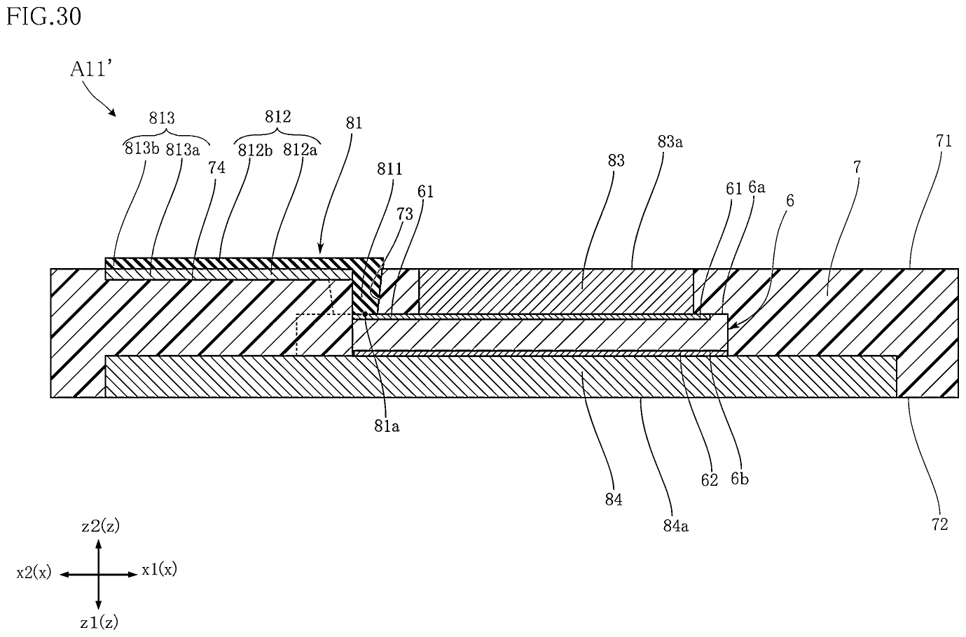

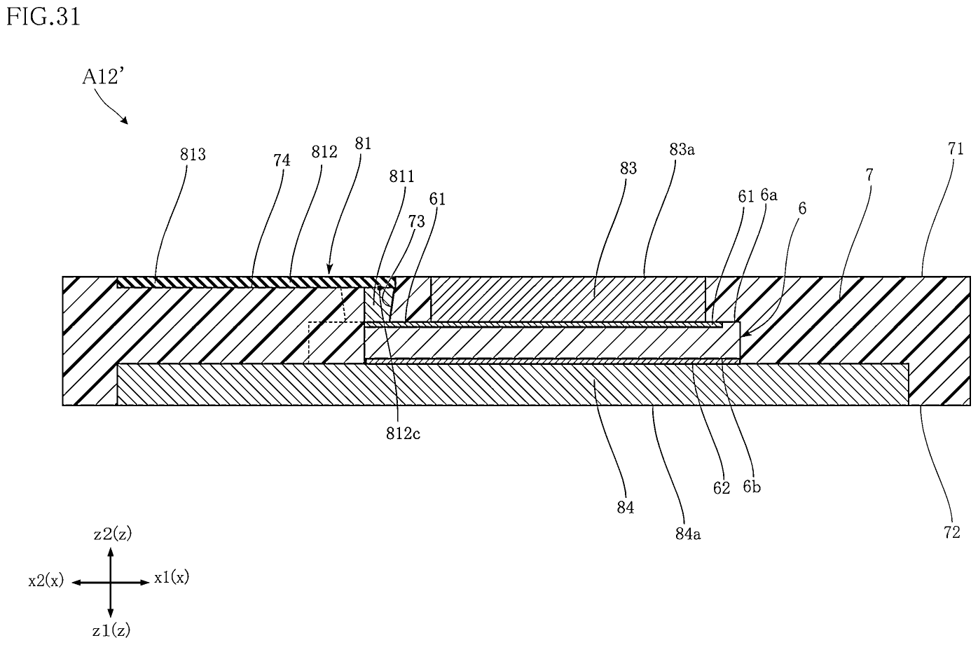

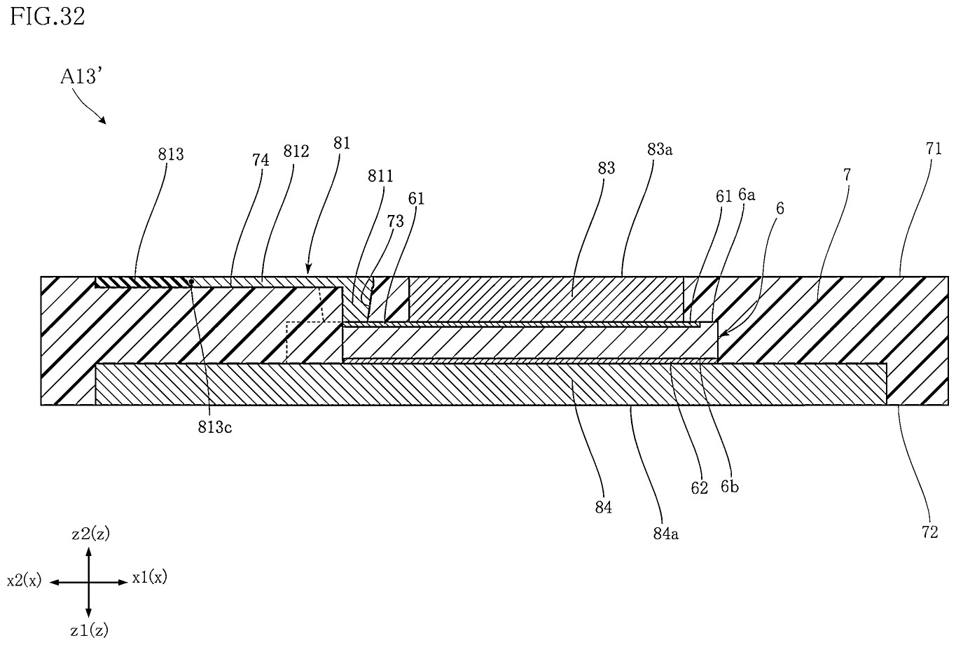

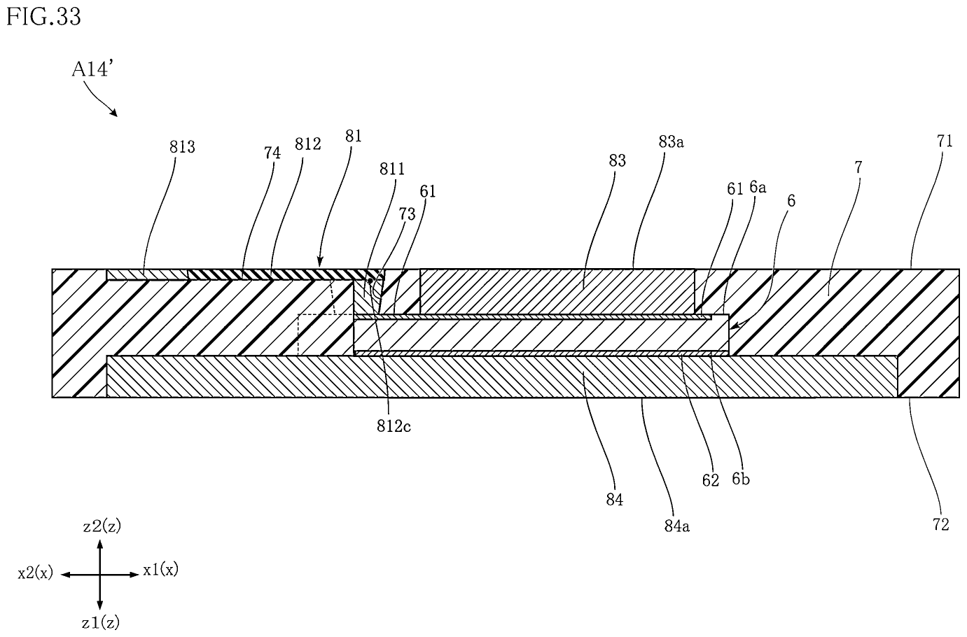

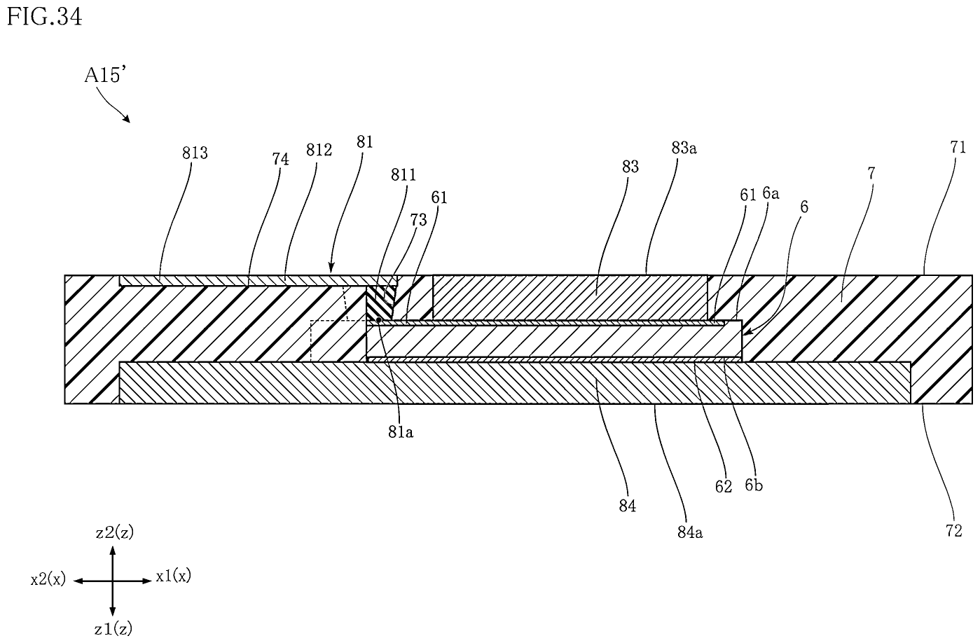

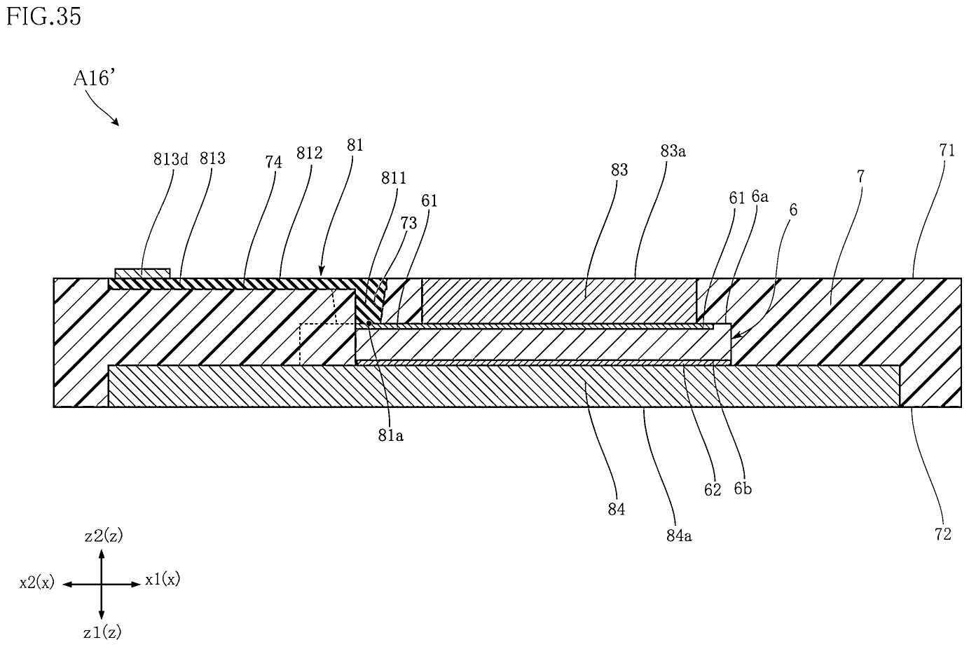

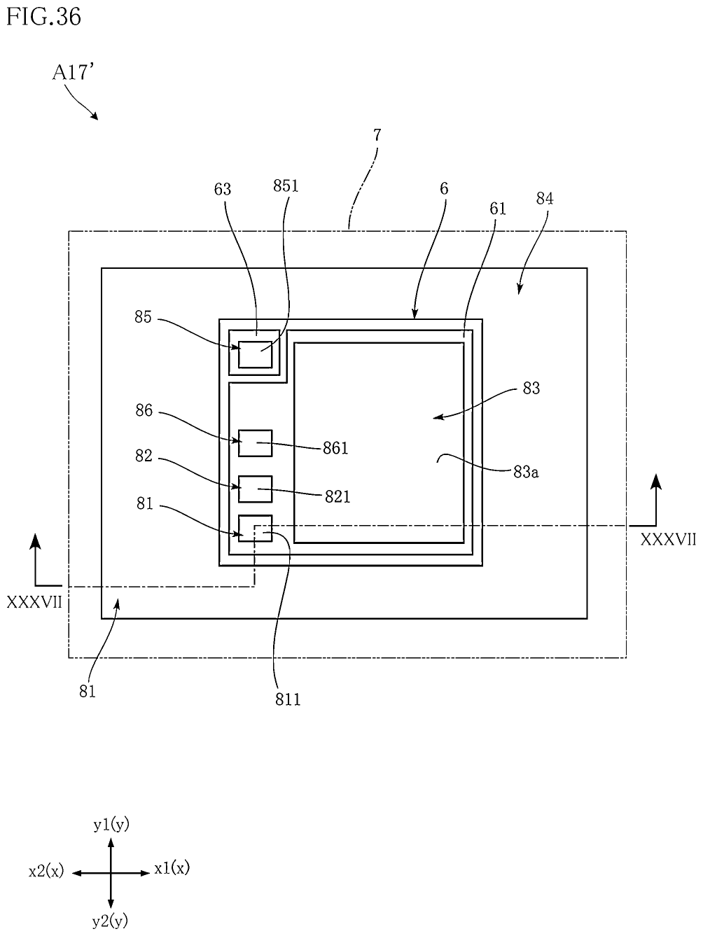

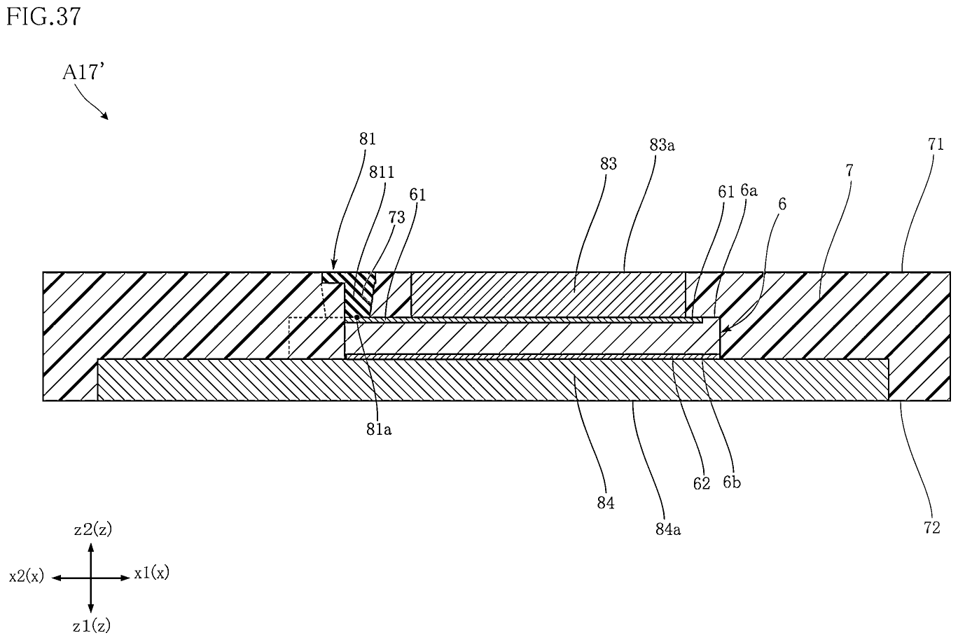

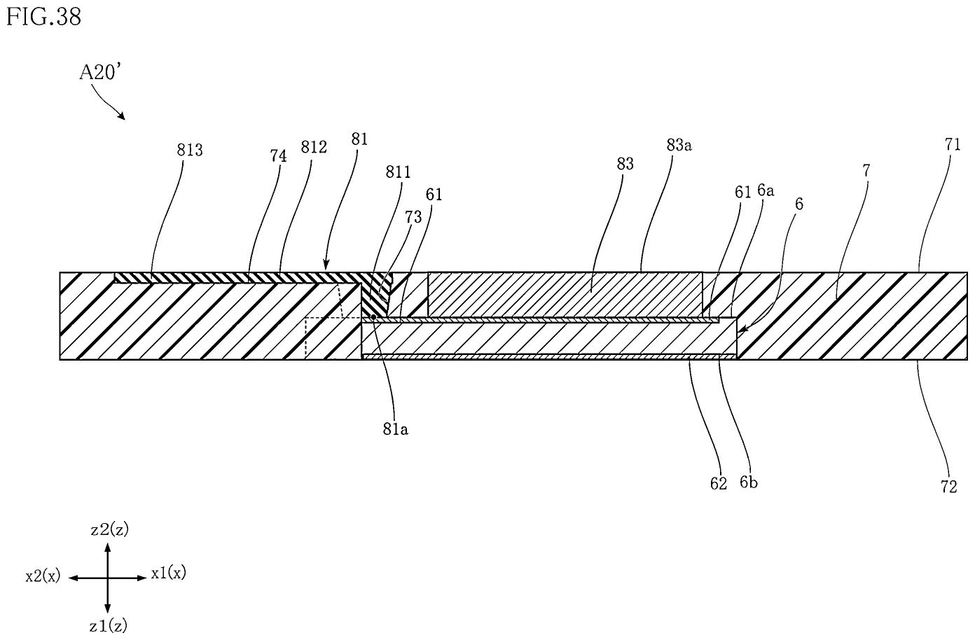

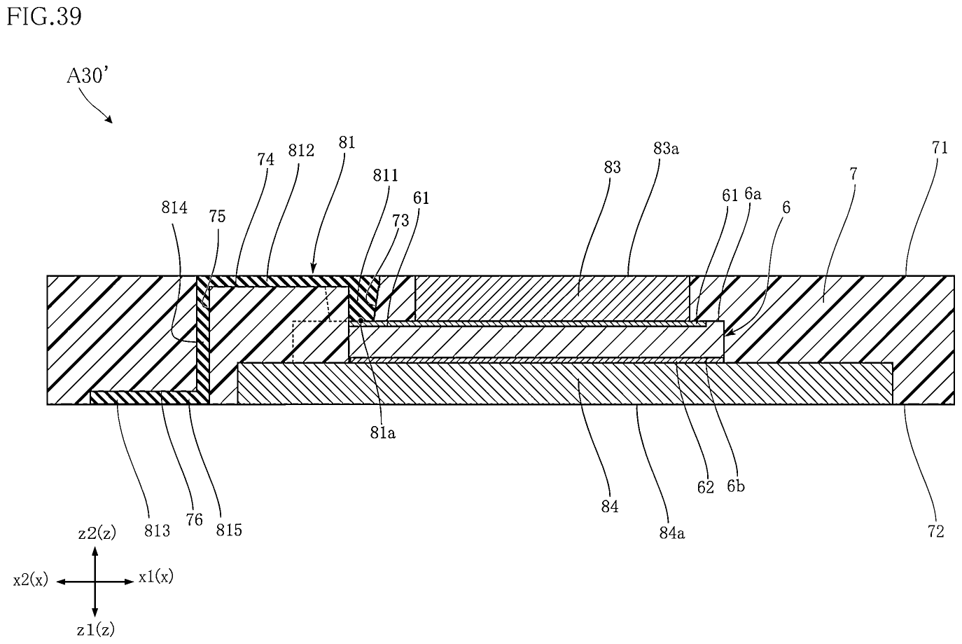

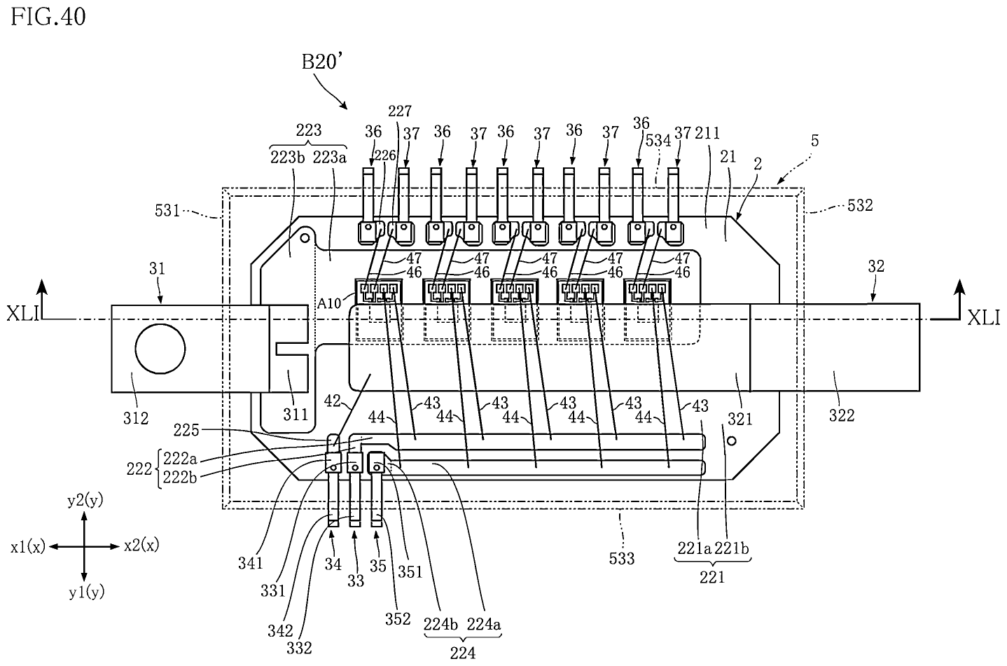

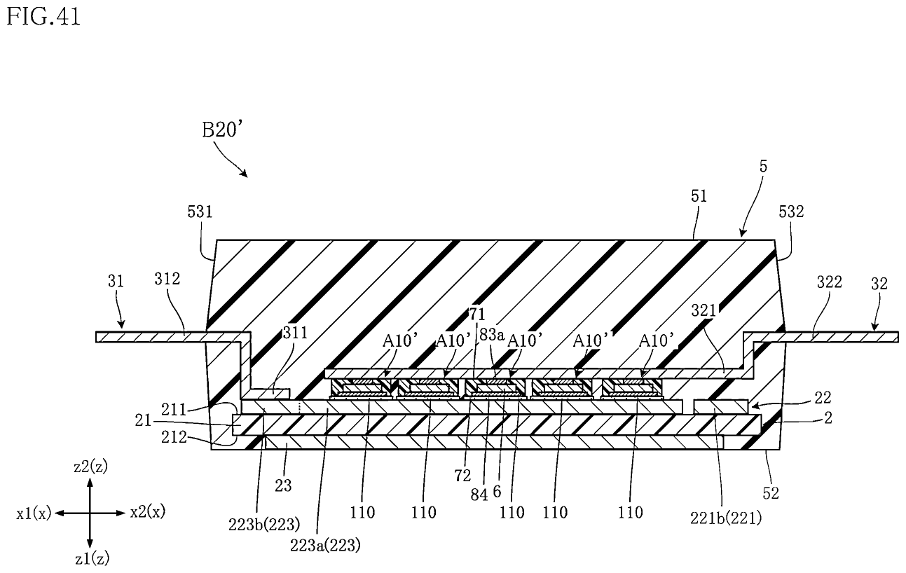

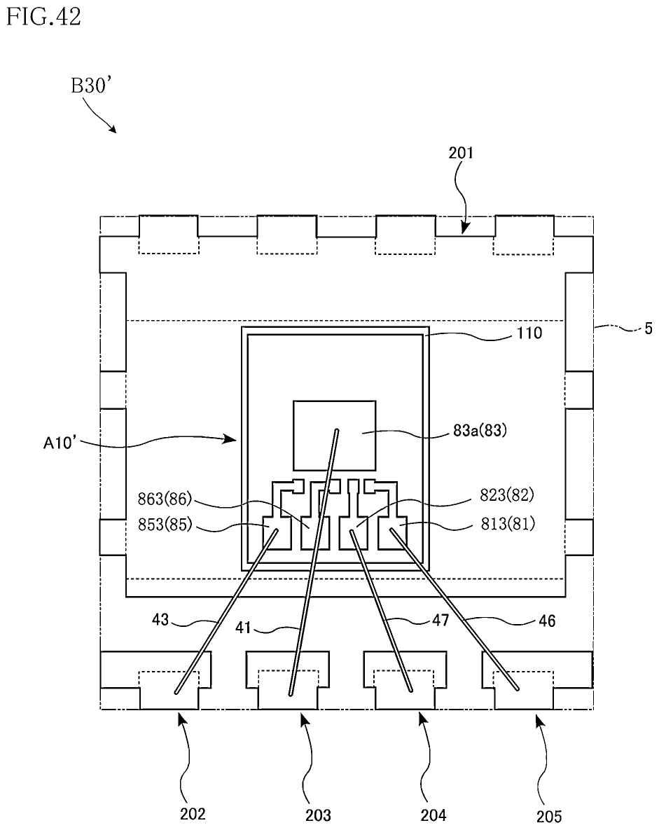

FIG. 1 is a perspective view showing the semiconductor device A10. FIG. 2 is a plan view showing the semiconductor device A10. FIG. 3 is a cross-sectional view along line III-III in FIG. 2. FIG. 4 is a cross-sectional view along line IV-IV in FIG. 2. For convenience of understanding, FIG. 2 shows the sealing resin 4 as transparent, and the sealing resin 4 is indicated by an imaginary line. FIG. 4 omits the wires 3.

In the description of the semiconductor device A10, the thickness direction of the semiconductor element 2 is referred to as a “thickness direction z”. A direction perpendicular to the thickness direction z is referred to as a “first direction x”. The direction perpendicular to the thickness direction z and the first direction x is referred to as a “second direction y”. As shown in FIG. 2, the semiconductor device A10 has a rectangular shape (or substantially a rectangular shape) as viewed in the thickness direction z. The size of the semiconductor device A10 is not particularly limited.

The first lead 1A, the second lead 1B, the third lead 1C, the fourth lead 1D, and the fifth lead 1E are formed by punching or bending a metal plate (a lead frame), for example. The constituent material of each of the first lead 1A to the fifth lead 1E is not particularly limited, and may be copper (Cu), nickel (Ni), or an alloy of one of these metals. A part of the surface of each of the first lead 1A to the fifth lead 1E may be plated for corrosion resistance, electrical conductivity, thermal conductivity, or bondability, for example.

As shown in FIGS. 2 and 4, the third lead 1C has a die pad 131, a third terminal portion 132, and an intermediate bent portion 133. The die pad 131 has a rectangular shape as viewed in the thickness direction z, for example. The die pad 131 has a first surface 131a and a pad reverse surface 131b. The first surface 131a faces a first side in the thickness direction z, and the pad reverse surface 131b faces the opposite side (a second side in the thickness direction z) from the first surface 131a. The semiconductor element 2 is mounted on the first surface 131a.

In the present embodiment, the die pad 131 is formed with a through-hole 131c passing from the first surface 131a to the pad reverse surface 131b. As viewed in the thickness direction z, the through-hole 131c is spaced apart from the semiconductor element 2. Although the through-hole 131c has a circular shape as viewed in the thickness direction z, it is not limited to a particular shape. The die pad 131 corresponds to an example of a “base”.

The third terminal portion 132 is located on a first side in the first direction x relative to the die pad 131. The third terminal portion 132 is continuous to the die pad 131 on the first side in the first direction x, and extends to the first side in the first direction x. As shown in FIG. 2, the third terminal portion 132 of the present embodiment is continuous to a first end (lower end in the figure) of the die pad 131 in the first direction x and to the middle of the die pad 131 in the second direction y, as viewed in the thickness direction z.

As shown in FIG. 2, the fourth lead 1D is spaced apart from the die pad 131 to the first side in the first direction x, and extends in the first direction x. The fourth lead 1D has a fourth pad portion 141 and a fourth terminal portion 142. The fourth pad portion 141 is arranged at the end of the fourth lead 1D on a second side in the first direction x. The fourth terminal portion 142 is continuous to the fourth pad portion 141, and extends to the first side in the first direction x relative to the die pad 131. The fourth terminal portion 142 is located on a second side in the second direction y relative to the third terminal portion 132.

The fifth lead 1E is spaced apart from the die pad 131 to the first side in the first direction x, and extends in the first direction x. The fifth lead 1E has a fifth pad portion 151 and a fifth terminal portion 152. The fifth pad portion 151 is arranged at the end of the fifth lead 1E on the second side in the first direction x. The fifth terminal portion 152 is continuous to the fifth pad portion 151, and extends to the first side in the first direction x relative to the die pad 131. The fifth terminal portion 152 is located on a first side in the second direction y relative to the third terminal portion 132.

The first lead 1A is spaced apart from the die pad 131 to the first side in the first direction x, and extends in the first direction x. The first lead 1A has a first pad portion 111 and a first terminal portion 112. The first pad portion 111 is arranged at the end of the first lead 1A on the second side in the first direction x. The first terminal portion 112 is continuous to the first pad portion 111, and extends to the first side in the first direction x relative to the die pad 131. The first terminal portion 112 is located on the first side in the second direction y relative to the fifth terminal portion 152.

The second lead 1B is spaced apart from the die pad 131 to the first side in the first direction x, and extends in the first direction x. The second lead 1B has a second pad portion 121 and a second terminal portion 122. The second pad portion 121 is arranged at the end of the second lead 1B on the second side in the first direction x. The second terminal portion 122 is continuous to the second pad portion 121, and extends to the first side in the first direction x relative to the die pad 131. The second terminal portion 122 is located on the first side in the second direction y relative to the first terminal portion 112.

As shown in FIG. 2, the first terminal portion 112, the second terminal portion 122, the third terminal portion 132, the fourth terminal portion 142, and the fifth terminal portion 152 are spaced apart from each other in the second direction y and exposed from the sealing resin 4. One of the first terminal portion 112 and the second terminal portion 122 out of the terminal portions 112, 122, 132, 142, and 152 is located at the outermost position in the second direction y. In the present embodiment, the second terminal portion 122 is located at the end on the first side in the second direction y. The first terminal portion 112 and the second terminal portion 122 are adjacent to each other in the second direction y.

In the present embodiment, as shown in FIG. 2, the first pad portion 111 and the second pad portion 121 are offset from the fourth pad portion 141 and the fifth pad portion 151 to the first side in the first direction x. In other words, the first pad portion 111 and the second pad portion 121 are farther away from the die pad 131 than the fourth pad portion 141 and the fifth pad portion 151.

The semiconductor element 2 is an element that performs an electrical function of the semiconductor device A10. The type of the semiconductor element 2 is not particularly limited. In the present embodiment, the semiconductor element 2 is configured as a transistor, and is a switching element made with the use of Si or Sic as a base material. As shown in FIGS. 2 to 4, the semiconductor element 2 has an element body 20, a source electrode 21, a drain electrode 22, and a gate electrode 23.

The element body 20 has a rectangular shape as viewed in the thickness direction z. The element body 20 has an element obverse surface 201 and an element reverse surface 202. The element obverse surface 201 and the element reverse surface 202 face away from each other in the thickness direction z. The element obverse surface 201 faces the same side as the first surface 131a of the die pad 131 in the thickness direction z. Thus, the element reverse surface 202 faces the first surface 131a.

The source electrode 21 and the gate electrode 23 are arranged on the element obverse surface 201. The drain electrode 22 is arranged on the element reverse surface 202. In the present embodiment, the source electrode 21 covers most of the element obverse surface 201, and is much larger than the gate electrode 23. The semiconductor element 2 applies a driving voltage to the gate electrode 23 and the source electrode 21 with a potential difference between the drain electrode 22 and the source electrode 21, thereby performing the on/off control of the drain electrode 22 and the source electrode 21. The constituent material of each of the source electrode 21, the drain electrode 22, and the gate electrode 23 is not particularly limited, and may be Cu, aluminum (Al), or an alloy of one of these metals.

The drain electrode 22 is electrically connected to the first surface 131a (the die pad 131) via a conductive bonding material 61. The conductive bonding material 61 electrically connects the die pad 131 and the drain electrode 22. The conductive bonding material 61 is solder, for example. The third terminal portion 132 is electrically connected to the drain electrode 22 via the die pad 131 and the conductive bonding material 61. In the present embodiment, the third terminal portion 132 is a drain terminal of the semiconductor device A10.

As shown in FIG. 2, each of the wires 3 has an end connected to the semiconductor element 2. In the present embodiment, the wires 3 include a first wire 31, a second wire 32, a fourth wire 34, and a fifth wire 35.

The fourth wire 34 is connected to the gate electrode 23 of the semiconductor element 2 and the fourth pad portion 141 of the fourth lead 1D, and electrically connects the gate electrode 23 and the fourth terminal portion 142. In the present embodiment, the fourth terminal portion 142 is a gate terminal of the semiconductor device A10. The fifth wire 35 is connected to the source electrode 21 of the semiconductor element 2 and the fifth pad portion 151 of the fifth lead 1E, and electrically connects the source electrode 21 and the fifth terminal portion 152. In the present embodiment, the fifth terminal portion 152 is a source terminal of the semiconductor device A10. In the present embodiment, the diameter of the fifth wire 35 is larger than that of the fourth wire 34. Further, a plurality of (two) fifth wires 35 are connected to the source electrode 21 and the fifth pad portion 151. The fourth wire 34 and the fifth wires 35 may be made of Al, an Al alloy, Cu, or a Cu alloy.

The first wire 31 is connected to the source electrode 21 and the first pad portion 111 of the first lead 1A, and electrically connects the source electrode 21 and the first terminal portion 112. The second wire 32 is connected to the source electrode 21 and the second pad portion 121 of the second lead 1B, and electrically connects the source electrode 21 and the second terminal portion 122.

The first wire 31 and the second wire 32 are made of metals having different thermoelectric powers. Each of the first wire 31 and the second wire 32 has an end connected to the common source electrode 21. The first wire 31 and the second wire 32 are metal wires that function as a thermocouple. The first terminal portion 112, which is electrically connected to the first wire 31 via the first pad portion 111, and the second terminal portion 122, which is electrically connected to the second wire 32 via the second pad portion 121, are external connection terminals for temperature measurement. The source electrode 21 corresponds to an example of a “first electrode”.

The constituent material of each of the first wire 31 and the second wire 32 is not particularly limited. For example, one of the first wire 31 and the second wire 32 may be made of Chromel and the other may be made of Alumel. Alternatively, one of the first wire 31 and the second wire 32 may be made of Chromel and the other may be made of constantan.

The sealing resin 4 covers the semiconductor element 2, a portion of each of the first lead 1A to the fifth lead 1E, and the wires 3 (the first wire 31, the second wire 32, the fourth wire 34, and the fifth wires 35) to protect them. More specifically, the sealing resin 4 covers at least a portion of the die pad 131 of the third lead 1C, a portion of the fourth lead 1D (mainly the fourth pad portion 141), a portion of the fifth lead 1E (mainly the fifth pad portion 151), a portion of the first lead 1A (mainly the first pad portion 111), and a portion of the second lead 1B (mainly the second pad portion 121). The sealing resin 4 is a synthetic resin that is electrically insulative. The constituent material of the sealing resin 4 may be, but not limited to, black epoxy resin.

As shown in FIGS. 1, 3, and 4, the sealing resin 4 has a resin obverse surface 41, a resin reverse surface 42, and resin side surfaces 43 to 46. The resin obverse surface 41 and the resin reverse surface 42 face away from each other in the thickness direction z. The resin obverse surface 41 faces the first side in the thickness direction z, and faces the same side as the element obverse surface 201 and the first surface 131a. The resin reverse surface 42 faces the second side in the thickness direction z, and faces the same side as the element reverse surface 202 and the pad reverse surface 131b.

Each of the resin side surfaces 43 to 46 is connected to the resin obverse surface 41 and the resin reverse surface 42, and is located between the resin obverse surface 41 and the resin reverse surface 42 in the thickness direction z. The resin side surface 43 and the resin side surface 44 face away from each other in the first direction x. The resin side surface 43 faces the first side in the first direction x, and the resin side surface 44 faces the second side in the first direction x. The resin side surface 45 and the resin side surface 46 face away from each other in the second direction y. The resin side surface 45 faces the first side in the second direction y, and the resin side surface 46 faces the second side in the second direction y. In the present embodiment, a portion of each of the first terminal portion 112, the second terminal portion 122, the third terminal portion 132, the fourth terminal portion 142, and the fifth terminal portion 152 protrudes from the resin side surface 43.

In the present embodiment, the sealing resin 4 is formed with a pair of recesses 47 recessed into the sealing resin 4 from the upper portions of the pair of resin side surfaces 45 and 46 shown in FIG. 1. Further, as shown in FIGS. 1 and 4, the sealing resin 4 is formed with a resin through-hole 48 extending from the resin obverse surface 41 to the resin reverse surface 42. In the present embodiment, the center of the resin through-hole 48 coincides with the center of the through-hole 131c in the die pad 131. The diameter of the resin through-hole 48 is smaller than the diameter of the through-hole 131c. In the present embodiment, the wall of the through-hole 131c is completely covered with the sealing resin 4.

The following describes advantages of the present embodiment.

The semiconductor device A10 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to the source electrode 21 (the first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A10 can measure the temperature of the semiconductor element 2 without having a temperature sensor or the like built therein. This makes it possible to measure the temperature of the semiconductor element 2 when it is driven without taking much space.

In the semiconductor device A10, the first terminal 112, the second terminal portion 122, the third portion terminal portion 132, the fourth terminal portion 142, and the fifth terminal portion 152 are arranged on the first side in the first direction x relative to the die pad 131. The first terminal portion 112 to the fifth terminal portion 152 are spaced apart from each other in the second direction y, and one of the first terminal portion 112 and the second terminal portion 122 is located at the outermost position in the second direction y. In the example shown in FIG. 2, the second terminal portion 122 is located at the end on the first side in the second direction y. The first terminal portion 112 and the second terminal portion 122 are adjacent to each other in the second direction y. According to such a configuration, the first wire 31 and the second wire 32 are relatively long. Thus, the first terminal portion 112 and the second terminal portion 122 for temperature measurement are less affected by the heat conducted via the first wire 31 and the second wire 32 from the semiconductor element 2, which is a heat generating source. This improves the accuracy of temperature measurement of the semiconductor element 2 in the semiconductor device A10.

The first pad portion 111 and the second pad portion 121 are located on the first side in the first direction x than the fourth pad portion 141 and the fifth pad portion 151. In other words, the first pad portion 111 to which the first wire 31 is connected and the second pad portion 121 to which the second wire 32 is connected are farther away from the die pad 131 than the fourth pad portion 141 and the fifth pad portion 151. Such a configuration can increase the length of each of the first wire 31 and the second wire 32 to further improve the accuracy of temperature measurement of the semiconductor element 2 in the semiconductor device A10.

The semiconductor element 2 is a switching element having the source electrode 21, the drain electrode 22, and the gate electrode 23. The first wire 31 and the second wire 32 that function as a thermocouple are connected to the source electrode 21 of the semiconductor element 2 (the switching element). According to such a configuration, the temperature of the semiconductor element 2 can be measured with the source electrode 21, which reaches a high temperature, serving as a temperature measuring junction. This is more preferable for improving the accuracy of the measured temperature of the semiconductor element 2 in the semiconductor device A10.

Of the wires (the first wire 31 and the second wire 32) used as the thermocouple described above, the first wire 31 may be made of the same metal material as the source electrode 21 (the first electrode). In this case, the constituent material of the first wire 31 may be Al, an Al alloy, Cu, or a Cu alloy. When the first wire 31 and the source electrode 21 are made of the same metal material, the accuracy of temperature measurement of the semiconductor element 2 in the semiconductor device A10 can be further improved.

Alternatively, of the wires (the first wire 31 and the second wire 32) used as the thermocouple, the first wire 31 may be made of the same metal material as the first lead 1A (the first terminal portion 112) and the second wire 32 may be made of the same metal material as the second lead 1B (the second terminal portion 122) . . . . In this case, the constituent material of each of the first wire 31 and the second wire 32 may be selected from among Al, an Al alloy, Cu, and a Cu alloy under the condition that the constituent material of the first wire 31 is different from that of the second wire 32. When the first wire 31 and the first lead 1A are made of the same metal material and the second wire 32 and the second lead 1B are also made of the same metal material, the accuracy of temperature measurement of the semiconductor element 2 in the semiconductor device A10 can be further improved.

The example where the first wire 31 and the source electrode 21 can be made of the same metal material, and the example where the first wire 31 and the first lead 1A can be made of the same metal material and the second wire 32 and the second lead 1B can also be made of the same metal material are applicable to the variations and other embodiments described below.

### First Variation of the First Embodiment (First Aspect)

FIG. 5 shows a semiconductor device A11 according to a first variation of the first embodiment (the first aspect). FIG. 5 is a plan view showing the semiconductor device A11. FIG. 5 shows the sealing resin 4 as transparent, and the sealing resin 4 is indicated by an imaginary line. In FIG. 5 and the subsequent figures, the elements that are identical with or similar to those of the semiconductor device A10 in the above embodiment are designated by the same reference numerals as in the above embodiment, and the descriptions thereof are omitted as appropriate.

The semiconductor device A11 of the present variation does not include the fifth lead 1E. Accordingly, some changes have been made to the semiconductor device A11 as appropriate as compared to the semiconductor device A10.

In the semiconductor device A11, the first pad portion 111 and the second pad portion 121 are substantially at the same position as the fourth pad portion 141 in the first direction x. Each of the fifth wires 35 is connected to the source electrode 21 of the semiconductor element 2 and the first pad portion 111 of the first lead 1A, and electrically connects the source electrode 21 and the first terminal portion 112. In the present variation, the first terminal portion 112 is a temperature measurement terminal, and also functions as a source terminal of the semiconductor device A11.

The semiconductor device A11 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to the source electrode 21 (the first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A11 can measure the temperature of the semiconductor element 2 without having a temperature sensor or the like built therein. This makes it possible to measure the temperature of the semiconductor element 2 when it is driven without taking much space.

In the semiconductor device A11, the first terminal portion 112 for temperature measurement also functions as a source terminal. The source terminal (the first terminal portion 112) is connected to the ground, which is a reference potential, and the potential is stable at substantially 0 V. The source terminal (the first terminal portion 112) is also used for temperature measurement, so that the temperature of the semiconductor element 2 can be measured stably. Such a configuration is suitable for suppressing an increase in the number of terminals as well as measuring the temperature of the semiconductor element 2 (the switching element) stably when the semiconductor element 2 is driven. Further, the semiconductor device A11 has the same advantages as the semiconductor device A10 in the above embodiment within the range of the same configuration as that of the semiconductor device A10.

### Second Variation of the First Embodiment (First Aspect)

FIG. 6 shows a semiconductor device A12 according to a second variation of the first embodiment (the first aspect). FIG. 6 is a plan view showing the semiconductor device A12. FIG. 6 shows the sealing resin 4 as transparent, and the sealing resin 4 is indicated by an imaginary line.

The semiconductor device A12 of the present variation is different from the semiconductor device A10 mainly in the arrangement of the gate electrode 23 of the semiconductor element 2, the arrangement of the third terminal portion 132, the arrangement of the fourth lead 1D, and the arrangement of the fifth lead 1E.

In the semiconductor device A12, the third terminal portion 132 is continuous to the first end (the lower end in the figure) of the die pad 131 in the first direction x and the end of the die pad 131 on the second side in the second direction y. The fourth lead 1D is adjacent to the first lead 1A on the second side in the second direction y. The fifth lead 1E is adjacent to the fourth lead 1D on the second side in the second direction y. In the semiconductor device A12, the first pad portion 111 and the second pad portion 121 are substantially at the same position as the fourth pad portion 141 and the fifth pad portion 151 in the first direction x.

The semiconductor device A12 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to the source electrode 21 (the first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A12 can measure the temperature of the semiconductor element 2 without having a temperature sensor or the like built therein. This makes it possible to measure the temperature of the semiconductor element 2 when it is driven without taking much space. Further, the semiconductor device A12 has the same advantages as the semiconductor device A10 in the above embodiment within the range of the same configuration as that of the semiconductor device A10.

Third variation of the first embodiment (first aspect):

FIG. 7 shows a semiconductor device A13 according to a third variation of the first embodiment (the first aspect). FIG. 7 is a plan view showing the semiconductor device A13. FIG. 7 shows the sealing resin 4 as transparent, and the sealing resin 4 is indicated by an imaginary line.

The semiconductor device A13 of the present variation is different from the semiconductor device A12 mainly in the configuration of the semiconductor element 2 and further including a sixth lead 1F.

In the semiconductor device A13, the semiconductor element 2 further includes a source sense electrode 24. The source sense electrode 24 is arranged on the element obverse surface 201. The sixth lead 1F is arranged between the fourth lead 1D and the fifth lead 1E in the second direction y. The sixth lead 1F has a sixth pad portion 161 and a sixth terminal portion 162. The sixth pad portion 161 is arranged at the end of the sixth lead 1F on the second side in the first direction x. The sixth terminal portion 162 is continuous to the sixth pad portion 161, and extends to the first side in the first direction x relative to the die pad 131.

The wires 3 further include a sixth wire 36. The sixth wire 36 is connected to the source sense electrode 24 of the semiconductor element 2 and the sixth pad portion 161 of the sixth lead 1F, and electrically connects the source sense electrode 24 and the sixth terminal portion 162. The sixth terminal portion 162 is a s source sense terminal of the semiconductor device A13. The sixth terminal portion 162 detects the voltage applied to the source electrode 21 of the semiconductor element 2.

The semiconductor device A13 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to the source electrode 21 (the first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A13 can measure the temperature of the semiconductor element 2 without having a temperature sensor or the like built therein. This makes it possible to measure the temperature of the semiconductor element 2 when it is driven without taking much space. Further, the semiconductor device A13 has the same advantages as the semiconductor device A10 in the above embodiment within the range of the same configuration as that of the semiconductor device A10.

### Second Embodiment (First Aspect)

FIGS. 8 to 13 show a semiconductor device A20 according to a second embodiment (the first aspect) of the present disclosure. The semiconductor device A20 includes a first lead 1A, a second lead 1B, a third lead 1C, a fourth lead 1D, a fifth lead 1E, a semiconductor element 2, a plurality of wires 3, and a sealing resin 4. FIG. 8 is a perspective view showing the semiconductor device A20. FIG. 9 is a plan view showing the semiconductor device A20. FIG. 10 is a cross-sectional view along line X-X in FIG. 9. FIG. 11 is a cross-sectional view along line XI-XI in FIG. 9. FIG. 12 is a cross-sectional view along line XII-XII in FIG. 9. FIG. 13 is a cross-sectional view along line XIII-XIII in FIG. 9. For convenience of understanding, FIG. 9 shows the sealing resin 4 as transparent, and the sealing resin 4 is indicated by an imaginary line. The semiconductor device A20 is different from the semiconductor A10 device in the specific configurations of the first lead 1A to the fifth lead 1E.

As shown in FIGS. 9 to 13, the third lead 1C has a die pad 131, a third terminal portion 132, a connecting portion 134, an extending portion 136, and an engaging portion 137. The die pad 131 has a first surface 131a and a mounting surface 131d. The mounting surface 131d faces the opposite side (the second side in the thickness direction z) from the first surface 131a. The mounting surface 131d is exposed from the sealing resin 4. When the semiconductor device A20 is mounted on a circuit board (not illustrated), the mounting surface 131d is bonded to the circuit board with a bonding material such as solder.

The third terminal portion 132 is arranged on the second side in the first direction x relative to the die pad 131. The third terminal portion 132 is elongated in the second direction y. The connecting portion 134 connects the die pad 131 and the third terminal portion 132. The illustrated connecting portion 134 has a through-hole 135. The through-hole 135 penetrates through the connecting portion 134 in the thickness direction z.

As viewed in the thickness direction z, the extending portion 136 is continuous to the first end (the lower end in the figure) of the die pad 131 in the first direction x, and extends to the first side in the first direction x. The shape of the extending portion 136 is not particularly limited. The engaging portion 137 has a shape protruding in the first direction x or in the second direction y from the periphery of the die pad 131. The engaging portion 137 may be provided to engage with a portion of the sealing resin 4 to increase the holding strength of the sealing resin 4 with respect to the die pad 131, for example.

As viewed in the thickness direction z, the first lead 1A, the second lead 1B, the fourth lead 1D, and the fifth lead 1E in the semiconductor device A20 are arranged in the same manner as in the semiconductor device A10. The first lead 1A has a bent portion 113. Similarly, the second lead 1B, the fourth lead 1D, and the fifth lead 1E have bent portions 123, 143, and 153, respectively.

The bent portion 113 is located between a first pad portion 111 and a first terminal portion 112 in the first direction x. The bent portion 113 connects the first pad portion 111 and the first terminal portion 112, and has a shape bent toward the second side in the thickness direction z as viewed in the second direction y. The bent portion 123 is located between a second pad portion 121 and a second terminal portion 122 in the first direction x. The bent portion 123 connects the second pad portion 121 and the second terminal portion 122, and has a shape bent toward the second side in the thickness direction z as viewed in the second direction y. The bent portion 143 is located between a fourth pad portion 141 and a fourth terminal portion 142 in the first direction x. The bent portion 143 connects the fourth pad portion 141 and the fourth terminal portion 142, and has a shape bent toward the second side in the thickness direction z as viewed in the second direction y. The bent portion 153 is located between a fifth pad portion 151 and a fifth terminal portion 152 in the first direction x. The bent portion 153 connects the fifth pad portion 151 and the fifth terminal portion 152, and has a shape bent toward the second side in the thickness direction z as viewed in the second direction y.

The semiconductor device A20 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to a source electrode 21 (a first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A20 can measure the temperature of the semiconductor element 2 without having a temperature sensor or the like built therein. This makes it possible to measure the temperature of the semiconductor element 2 when it is driven without taking much space. Further, the semiconductor device A20 has the same advantages as the semiconductor device A10 in the above embodiment within the range of the same configuration as that of the semiconductor device A10.

Variation of the second embodiment (first aspect):

FIG. 14 shows a semiconductor device A21 according to a variation of the second embodiment (the first aspect). FIG. 14 is a plan view showing the semiconductor device A21. FIG. 14 shows the sealing resin 4 as transparent, and the sealing resin 4 is indicated by an imaginary line. The semiconductor device A21 of the present variation does not include the fifth lead 1E. Accordingly, some changes have been made to the semiconductor device A21 as appropriate as compared to the semiconductor device A20.

A fifth wire 35 is connected to the source electrode 21 of the semiconductor element 2 and the first pad portion 111 of the first lead 1A, and electrically connects the source electrode 21 and the first terminal portion 112. In the present variation, the first t terminal portion 112 is a temperature measurement terminal, and also functions as a source terminal of the semiconductor device A21.

The semiconductor device A21 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to the source electrode 21 (the first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A21 can measure the temperature of the semiconductor element 2 without having a temperature sensor or the like built therein. This makes it possible to measure the temperature of the semiconductor element 2 when it is driven without taking much space.

In the semiconductor device A21, the first terminal portion 112 for temperature measurement also functions as a source terminal. The source terminal (the first terminal portion 112) is connected to the ground, which is a reference potential, and the potential is stable at substantially 0 V. The source terminal (the first terminal portion 112) is also used for temperature measurement, so that the temperature of the semiconductor element 2 can be measured stably. Such a configuration is suitable for suppressing an increase in the number of terminals as well as measuring the temperature of the semiconductor element 2 (the switching element) stably when the semiconductor element 2 is driven. Further, the semiconductor device A21 has the same advantages as the semiconductor device A10 in the above embodiment within the range of the same configuration as that of the semiconductor device A10.

### Third Embodiment (First Aspect)

FIGS. 15 to 20 show a semiconductor device A30 according to a third embodiment (the first aspect) of the present disclosure. The semiconductor device A30 includes a first lead 1A, a second lead 1B, a third lead 1C, a fourth lead 1D, a fifth lead 1E, a semiconductor element 2, a plurality of wires 3, and a sealing resin 4. FIG. 15 is a perspective view showing the semiconductor device A30. FIG. 16 is a perspective view showing the semiconductor device A30, with a bottom surface thereof facing upward. FIG. 17 is a plan view showing the semiconductor device A30. FIG. 18 is a bottom view showing the semiconductor device A30. FIG. 19 is a cross-sectional view along line XIX-XIX in FIG. 17. FIG. 20 is a cross-sectional view along line XX-XX in FIG. 17. For convenience of understanding, FIG. 17 shows the sealing resin 4 as transparent, and the sealing resin 4 is indicated by an imaginary line.

The semiconductor device A30 is surface-mountable on the circuit boards of various devices. The semiconductor device A30 is provided in a dual flatpack no-leaded (DFN) package. The semiconductor device A30 is different from the semiconductor device A10 in the specific configurations of the first lead 1A to the fourth lead 1D.

As shown in FIGS. 16 to 20, the third lead 1C has a die pad 131, a third terminal portion 132, a plurality of connecting end surfaces 138a, and a reverse-side recessed portion 138b. The die pad 131 has a first surface 131a and a mounting surface 131d. The mounting surface 131d faces the opposite side (the second side in the thickness direction z) from the first surface 131a. The mounting surface 131d is exposed from the sealing resin 4. When the semiconductor device A30 is mounted on a circuit board (not illustrated), the mounting surface 131d is bonded to the circuit board with a bonding material such as solder.

The third terminal portion 132 is arranged on the second side in the first direction x relative to the die pad 131. In the illustrated example, a plurality of (four) third terminal portions 132 are arranged at intervals in the second direction y. Each of the third terminal portions 132 has a terminal end surface 132a and a reverse surface 132b. The terminal end surface 132a faces the second side in the first direction x, and is exposed from the sealing resin 4. The terminal end surface 132a is flush with a resin side surface 44. The terminal end surface 132a is formed by dicing during a cutting step in the manufacturing process of the semiconductor device A30. The reverse surface 132b faces the second side in the thickness direction z, and is connected to the terminal end surface 132a. The reverse surface 132b is exposed from the sealing resin 4, and is flush with a resin reverse surface 42.

The reverse-side recessed portion 138b is where a portion of the third lead 1C is recessed from the mounting surface 131d to the first side in the thickness direction z, and is provided around the mounting surface 131d. The thickness (the dimension in the thickness direction z) of the portion of the third lead 1C where the reverse-side recessed portion 138b is located is about half the thickness of the portion of the third lead 1C where the mounting surface 131d is located. The reverse-side recessed portion 138b is formed by half-etching, for example. As shown in FIG. 18, the reverse-side recessed portion 138b is not exposed from the sealing resin 4, and is covered with the sealing resin 4. This can prevent the third lead 1C from peeling off from the sealing resin 4 to the second side in the thickness direction z.

The connecting end surfaces 138a face in the second direction y. The connecting end surfaces 138a are connected to the reverse-side recessed portion 138b, and are exposed from the sealing resin 4. The connecting end surfaces 138a are formed by dicing during the cutting step in the manufacturing process. In the present embodiment, the connecting end surfaces 138a include two connecting end surfaces 138a facing the first side in the second direction y and two connecting end surfaces 138a facing the second side in the second direction y. The two connecting end surfaces 138a facing the first side in the second direction y are separated from each other by the sealing resin 4 and aligned in the first direction x. The two connecting end surfaces 138a facing the second side in the second direction y are separated from each other by the sealing resin 4 and aligned in the first direction x.

As shown in FIGS. 17 and 18, the first lead 1A, the second lead 1B, and the fourth lead 1D are arranged on the first side in the first direction x relative to the die pad 131, and are spaced apart from each other. The first lead 1A, the second lead 1B, and the fourth lead 1D are spaced apart from each other in the second direction y. The first lead 1A is arranged on the second side in the second direction y in the semiconductor device A30. The second lead 1B is arranged on the first side in the second direction y relative to the first lead 1A. The fourth lead 1D is arranged on the first side in the second direction y relative to the second lead 1B.

As shown in FIGS. 17, 18, and 20, the first lead 1A has a first pad portion 111, a first terminal portion 112, a connecting end surface 114a, and a reverse-side recessed portion 114b. The first pad portion 111 is configured by a portion of the first lead 1A on the first side in the thickness direction z, and has an obverse surface 111a facing the first side in the thickness direction z. The first terminal portion 112 has a terminal end surface 112a and a reverse surface 112b. The terminal end surface 112a faces the first side in the first direction x, and is exposed from the sealing resin 4. The terminal end surface 112a is flush with a resin side surface 43. The terminal end surface 112a is formed by dicing during the cutting step in the manufacturing process of the semiconductor device A30. The reverse surface 112b faces the second side in the thickness direction z, and is connected to the terminal end surface 112a. The reverse surface 112b is exposed from the sealing resin 4, and is flush with the resin reverse surface 42.

The reverse-side recessed portion 114b is where a portion of the first lead 1A is recessed from the reverse surface 112b to the first side in the thickness direction z, and is provided around the reverse surface 112b. The thickness (the dimension in the thickness direction z) of the portion of the first lead 1A where the reverse-side recessed portion 114b is located is about half the thickness of the portion of the first lead 1A where the reverse surface 112b is located. The reverse-side recessed portion 114b is formed by half-etching, for example. As shown in FIG. 18, the reverse-side recessed portion 114b is not exposed from the sealing resin 4, and is covered with the sealing resin 4. This can prevent the first lead 1A from peeling off from the sealing resin 4 to the second side in the thickness direction z. The connecting end surface 114a faces the second side in the second direction y. The connecting end surface 114a is connected to the reverse-side recessed portion 114b, and is exposed from the sealing resin 4. The connecting end surface 114a is formed by dicing during the cutting step in the manufacturing process.

As shown in FIGS. 17 and 18, the second lead 1B has a second pad portion 121, a second terminal portion 122, and a reverse-side recessed portion 124b. The second pad portion 121 is configured by a portion of the second lead 1B on the first side in the thickness direction z, and has an obverse surface 121a facing the first side in the thickness direction z. The second terminal portion 122 has a terminal end surface 122a and a reverse surface 122b. The terminal end surface 122a faces the first side in the first direction x, and is exposed from the sealing resin 4. The terminal end surface 122a is flush with the resin side surface 43. The terminal end surface 122a is formed by dicing during the cutting step in the manufacturing process of the semiconductor device A30. The reverse surface 122b faces the second side in the thickness direction z, and is connected to the terminal end surface 122a. The reverse surface 122b is exposed from the sealing resin 4, and is flush with the resin reverse surface 42.

The reverse-side recessed portion 124b is where a portion of the second lead 1B is recessed from the reverse surface 122b to the first side in the thickness direction z, and is provided around the reverse surface 122b. The thickness (the dimension in the thickness direction z) of the portion of the second lead 1B where the reverse-side recessed portion 124b is located is about half the thickness of the portion of the second lead 1B where the reverse surface 122b is located. The reverse-side recessed portion 124b is formed by half-etching, for example. As shown in FIG. 18, the reverse-side recessed portion 124b is not exposed from the sealing resin 4, and is covered with the sealing resin 4. This can prevent the second lead 1B from peeling off from the sealing resin 4 to the second side in the thickness direction z.

As shown in FIGS. 17 and 18, the fourth lead 1D has a fourth pad portion 141, a fourth terminal portion 142, a connecting end surface 144a, and a reverse-side recessed portion 144b. The fourth pad portion 141 is configured by a portion of the fourth lead 1D on the first side in the thickness direction z, and has an obverse surface 141a facing the first side in the thickness direction z. The fourth terminal portion 142 has a terminal end surface 142a and a reverse surface 142b. The terminal end surface 142a faces the first side in the first direction x, and is exposed from the sealing resin 4. The terminal end surface 142a is flush with the resin side surface 43. The terminal end surface 142a is formed by dicing during the cutting step in the manufacturing process of the semiconductor device A30. The reverse surface 142b faces the second side in the thickness direction z, and is connected to the terminal end surface 142a. The reverse surface 142b is exposed from the sealing resin 4, and is flush with the resin reverse surface 42.

The reverse-side recessed portion 144b is where a portion of the fourth lead 1D is recessed from the reverse surface 142b to the first side in the thickness direction z, and is provided around the reverse surface 142b. The thickness (the dimension in the thickness direction z) of the portion of the fourth lead 1D where the reverse-side recessed portion 144b is located is about half the thickness of the portion of the fourth lead 1D where the reverse surface 142b is located. The reverse-side recessed portion 144b is formed by half-etching, for example. As shown in FIG. 18, the reverse-side recessed portion 144b is not exposed from the sealing resin 4, and is covered with the sealing resin 4. This can prevent the fourth lead 1D from peeling off from the sealing resin 4 to the second side in the thickness direction z. The connecting end surface 144a faces the first side in the second direction y. The connecting end surface 144a is connected to the reverse-side recessed portion 144b, and is exposed from the sealing resin 4. The connecting end surface 144a is formed by dicing during the cutting step in the manufacturing process.

The wires 3 include a first wire 31, a second wire 32, a fourth wire 34, and a fifth wire 35. The first wire 31 is connected to a source electrode 21 of the semiconductor element 2 and the obverse surface 111a (the first pad portion 111) of the first lead 1A, and electrically connects the source electrode 21 and the first terminal portion 112. The second wire 32 is connected to the source electrode 21 and the obverse surface 121a (the second pad portion 121) of the second lead 1B, and electrically connects the source electrode 21 and the second terminal portion 122. The first terminal portion 112 and the second terminal 122 portion are temperature measurement terminals.

The fourth wire 34 is connected to a gate electrode 23 and the obverse surface 141a (the fourth pad portion 141) of the fourth lead 1D, and electrically connects the gate electrode 23 and the fourth terminal portion 142. The fifth wire 35 is connected to the source electrode 21 and the obverse surface 111a (the first pad portion 111) of the first lead 1A, and electrically connects the source electrode 21 and the first terminal portion 112. In the present embodiment, a plurality of (four) fifth wires 35 are connected to the source electrode 21 and the first pad portion 111. In the present embodiment, the first terminal portion 112 is a temperature measurement terminal, and also functions a source terminal of the semiconductor device A30.

The semiconductor device A30 includes the first lead 1A, the second lead 1B, the third lead 1C, the semiconductor element 2, and the wires 3. The first lead 1A includes the first pad portion 111 and the first terminal portion 112, and the second lead 1B includes the second pad portion 121 and the second terminal portion 122. The third lead 1C includes the die pad 131 and the third terminal portion 132, and the semiconductor element 2 is mounted on the die pad 131. The wires 3 include the first wire 31 and the second wire 32. The first wire 31 and the second wire 32 are made of metals having different thermoelectric powers. The first wire 31 is connected to the source electrode 21 (a first electrode) of the semiconductor element 2 and the first pad portion 111. The second wire 32 is connected to the source electrode 21 (the first electrode) and the second pad portion 121.

With such a configuration, the first wire 31 and the second wire 32 function as a thermocouple that uses the source electrode 21, to which the first wire 31 and the second wire 32 are both connected, as a temperature measuring junction. The first terminal portion 112, which is electrically connected to the first wire 31 via the first pad portion 111, and the second terminal portion 122, which is electrically connected to the second wire 32 via the second pad portion 121, are temperature measurement terminals to be connected to a measuring instrument, and serve as reference junctions. When the temperature of the semiconductor element 2 is raised by the drive of the semiconductor element 2, the temperature of the source electrode 21 (the semiconductor element 2) can be measured through the thermoelectromotive force generated as a result of the temperature difference between the source electrode 21 that serves as a temperature measuring junction and the first terminal portion 112 (the second terminal portion 122) that serves as a reference junction. The semiconductor device A30 can measure the temperature of the semiconductor element 2 without having a temperature sensor or the like built therein. This makes it possible to measure the temperature of the semiconductor element 2 when it is driven without taking much space.

In the semiconductor device A30, the first terminal portion 112 for temperature measurement also functions as a source terminal. The source terminal (the first terminal portion 112) is connected to the ground, which is a reference potential, and the potential is stable at substantially 0 V. The source terminal (the first terminal portion 112) is also used for temperature measurement, so that the temperature of the semiconductor element 2 can be measured stably. Such a configuration is suitable for suppressing an increase in the number of terminals as well as measuring the temperature of the semiconductor element 2 (the switching element) stably when the semiconductor element 2 is driven. Further, the semiconductor device A30 has the same advantages as the semiconductor device A10 in the above embodiment within the range of the same configuration as that of the semiconductor device A10.

The semiconductor device according to the first aspect of the present disclosure is not limited to the above embodiments. Various design changes can be made to the specific configurations of the elements of the semiconductive device.

Next, embodiments according to a second aspect of the present disclosure will be described with reference to FIGS. 21 to 42. As described above, the reference numerals used in FIGS. 21 to 42 are provided independently from the reference numerals used in FIGS. 1 to 20.

### First Embodiment (Second Aspect)

The following describes semiconductor device A10′ according to a first embodiment (a second aspect) of the present disclosure, with reference to FIGS. 21 to 24. The semiconductor device A10′ includes a semiconductor element 6, conduction paths 81 to 86, and a sealing member 7. The semiconductor device A10′ is mounted in a semiconductor module, for example. The use and function of the semiconductor device A10′ are not particularly limited.

FIG. 21 is a perspective view showing the semiconductor device A10′. FIG. 22 is a plan view showing the semiconductor device A10′. For convenience of understanding, FIG. 22 shows the sealing member 7 in phantom, and the outer shape of the sealing member 7 is indicated by an imaginary line (two-dot chain line). FIG. 23 is a bottom view showing the semiconductor device A10′. FIG. 24 is a cross-sectional view along line XXIV-XXIV in FIG. 22.

The semiconductor device A10′ has a rectangular shape (or substantially a rectangular shape) as viewed in the thickness direction. For the convenience of description, the thickness direction of the semiconductor device A10′ is defined as a z direction, the direction (horizontal direction in FIG. 22) along a side of the semiconductor device A10′ and perpendicular to the z direction is defined as an x direction, and the direction (vertical direction in FIG. 22) perpendicular to the z direction and the x direction is defined as a y direction. The z direction corresponds to an example of the “thickness direction”. The dimensions of the semiconductor device A10′ are not particularly limited.

The semiconductor element 6 is an element that performs an electrical function of the semiconductor device A11′. The semiconductor element 6 is made of a semiconductor material mainly containing silicon carbide (SiC), for example. The semiconductor material is not limited to SiC, and may be silicon (Si), gallium arsenide (GaAs), or gallium nitride (GaN), for example. The semiconductor element 6 is a switching element such as a metal-oxide-semiconductor field-effect transistor (MOSFET). The semiconductor element 6 is not limited to a MOSFET, and may be a field effect transistor such as a metal-insulator-semiconductor FET (MISFET), or a bipolar transistor such as an insulated gate bipolar transistor (IGBT). The semiconductor element 6 is an n-channel MOSFET, for example. Alternatively, the semiconductor element 6 may be a p-channel MOSFET.

The semiconductor element 6 has an element obverse surface 6a and an element reverse surface 6b. The element obverse surface 6a and the element reverse surface 6b face away from each other in the z direction. The element obverse surface 6a faces a z2 side in the z direction. The element reverse surface 6b faces a z1 side in the z direction. The semiconductor element 6 also has a first electrode 61, a second electrode 62, and a third electrode 63. The first electrode 61 and the third electrode 63 are arranged on the element obverse surface 6a. The first electrode 61 is larger than the third electrode 63 in plan view. The second electrode 62 is arranged on the element reverse surface 6b. The second electrode 62 is arranged on almost the entirety of the element reverse surface 6b. The constituent material of the first electrode 61, the second electrode 62, and the third electrode 63 is not particularly limited, but is Cu in the present embodiment. In the semiconductor element 6 that comprises a MOSFET, the first electrode 61 is a source electrode, the second electrode 62 is a drain electrode, and the third electrode 63 is a gate electrode.

The sealing member 7 is electrically insulative and covers the semiconductor element 6. The sealing member 7 contains a thermosetting synthetic resin, for example. The synthetic resin may be epoxy resin or polyimide resin. In the present embodiment, the sealing member 7 may be formed by stacking a plurality of prepreg layers in a semi-cured state. The prepreg layers are plate-like members obtained by impregnating a reinforcing material, such as glass fiber, with epoxy resin. Alternatively, the sealing member 7 may be an epoxy resin molding material containing a filler material, for example. Note that the structure, material and forming method of the sealing member 7 are not particularly limited.

The sealing member 7 includes an obverse surface 71 and a reverse surface 72. The obverse surface 71 and the reverse surface 72 face away from each other in the z direction. The obverse surface 71 faces the z2 side in the z direction. The reverse surface 72 faces the z1 side in the z direction. The sealing member 7 includes a plurality of recessed portions 73. As shown FIG. 24, each of the recessed portions 73 is recessed from the obverse surface 71 of the sealing member 7 to the z1 side in the z direction and extends to the semiconductor element 6. Each of the recessed portions 73 has a rectangular shape as viewed in the z direction. In the present embodiment, each of the recessed portions 73 is such that the area in a plane perpendicular to the z direction decreases as proceeding from the z2 side to the z1 side in the z direction. In the present embodiment, four recessed portions 73 are aligned in the y direction. The sealing member 7 also includes a plurality of grooves 74. As shown in FIG. 24, each of the grooves 74 is recessed from the obverse surface 71 in the z direction. Each of the grooves 74 is connected to a corresponding recessed portion 73. There are four grooves 74 in the present embodiment. The recessed portions 73 and the grooves 74 are formed by laser irradiation, for example. The recessed portions 73 and the grooves 74 may be formed by other methods.

Each of the conduction paths 81 to 86 is formed of a conductor and arranged on the sealing member 7. The conduction paths 81 to 86 constitute a portion of the conduction path between the semiconductor element 6 and a wiring board or the like on which the semiconductor device A10′ is mounted.

The conduction path 81 is connected to the first electrode 61 of the semiconductor element 6. The conduction path 81 has a connecting portion 811, an obverse-surface wiring 812, and a pad 813. The connecting portion 811 is accommodated in one of the recessed portions 73 of the sealing member 7, and is in contact with the first electrode 61 of the semiconductor element 6. As shown in FIG. 22, the connecting portion 811 of the present embodiment is accommodated in the recessed portion 73 closest to a y2 side in the y direction out of the four recessed portions 73. The connecting portion 811 is an embedded via, penetrates the sealing member 7 from the side (the z2 side in the z direction) on which the obverse surface 71 of the sealing member 7 is located, and is connected to the semiconductor element 6. As shown in FIG. 24, the connecting portion 811 has a side surface inclined to the z direction, and has a tapered shape of which sectional area perpendicular to the z direction becomes smaller as proceeding from the z2 side to the z1 side in the z direction. The connecting portion 811 is not limited to a particular shape.

The obverse-surface wiring 812 is directly connected to the connecting portion 811, and is arranged on the side (the z2 side in the z direction) of the sealing member 7 where the obverse surface 71 is located. More specifically, the obverse-surface wiring 812 is arranged in one of the grooves 74 of the sealing member 7. As shown in FIG. 22, the obverse-surface wiring 812 of the present embodiment has an L shape as viewed in the z direction, and has a portion extending from the connecting portion 811 to the y2 side in the y direction and a portion extending in the x direction. The pad 813 is directly connected to the obverse-surface wiring 812, and is arranged on the z2 side in the z direction of the sealing member 7. More specifically, the pad 813 is arranged in a portion of the groove 74 having the obverse-surface wiring 812 therein, where the portion is located at the end of the groove 74 on an x2 side in the x direction and has a larger width (dimension in the y direction). As viewed in the z direction, the pad 813 has a rectangular shape, and the dimension thereof in the y direction is larger than the width (the dimension in the y direction) of the obverse-surface wiring 812. The pad 813 is a portion to which a bonding wire is bonded when the semiconductor device A10′ is mounted. As shown in FIG. 24, the obverse-surface wiring 812 and the pad 813 of the present embodiment are entirely accommodated in the groove 74, and are flush with the obverse surface 71. Note that the obverse-surface wiring 812 and the pad 813 may protrude from the obverse surface 71 to the z2 side in the z direction, or may be recessed to the z1 side in the z direction. Alternatively, the sealing member 7 may not be formed with the grooves 74, and the obverse-surface wiring 812 and the pad 813 may be arranged on the obverse surface 71.

The conduction path 82 is connected to the first electrode 61 of the semiconductor element 6. The conduction path 82 has a connecting portion 821, an obverse-surface wiring 822, and a pad 823. The connecting portion 821 is accommodated in one of the recessed portions 73 of the sealing member 7, and is in contact with the first electrode 61 of the semiconductor element 6. As shown in FIG. 22, the connecting portion 821 of the present embodiment is accommodated in the recessed portion 73 arranged in the second position from the y2 side in the y direction out of the four recessed portions 73. The connecting portion 821 is an embedded via, and penetrates the sealing member 7 from the z2 side in the z direction to be connected to the semiconductor element 6. The connecting portion 821 has a tapered shape similar to the connecting portion 811. The connecting portion 821 is not limited to a particular shape.

The obverse-surface wiring 822 is directly connected to the connecting portion 821, and is arranged on the z2 side in the z direction of the sealing member 7. More specifically, the obverse-surface wiring 822 is arranged in one of the grooves 74 of the sealing member 7. As shown in FIG. 22, the obverse-surface wiring 822 of the present embodiment extends from the connecting portion 821 to the x2 side in the x direction. The pad 823 is directly connected to the obverse-surface wiring 822, and is arranged on the z2 side in the z direction of the sealing member 7. More specifically, the pad 823 is arranged in a portion of the groove 74 having the obverse-surface wiring 822 therein, where the portion is located at the end of the groove 74 on the x2 side in the x direction and has a larger width (dimension in the direction). As viewed in the z direction, the pad 823 has a rectangular shape, and the dimension thereof in the y direction is larger than the width (the dimension in the y direction) of the obverse-surface wiring 822. The pad 823 is a portion to which a bonding wire is bonded when the semiconductor device A10′ is mounted. In the present embodiment, the obverse-surface wiring 822 and the pad 823 are entirely accommodated in the groove 74, and are flush with the obverse surface 71, as in the obverse-surface wiring 812 and the pad 813. Note that the obverse-surface wiring 822 and the pad 823 may protrude from the obverse surface 71 to the z2 side in the z direction, or may be recessed to the z1 side in the z direction. Alternatively, the sealing member 7 may not be formed with the grooves 74, and the obverse-surface wiring 822 and the pad 823 may be arranged on the obverse surface 71.

The conduction path 86 is connected to the first electrode 61 of the semiconductor element 6. The conduction path 86 has a connecting portion 861, an obverse-surface wiring 862, and a pad 863. The connecting portion 861 is accommodated in one of the recessed portions 73 of the sealing member 7, and is in contact with the first electrode 61 of the semiconductor element 6. As shown in FIG. 22, the connecting portion 861 of the present embodiment is accommodated in the recessed portion 73 arranged in the second position from a y1 side in the y direction out of the four recessed portions 73. The connecting portion 861 is an embedded via, and penetrates the sealing member 7 from the z2 side in the z direction to be connected to the semiconductor element 6. The connecting portion 861 has a tapered shape similar to the connecting portion 811. The connecting portion 861 is not limited to a particular shape.

The obverse-surface wiring 862 is directly connected to the connecting portion 861, and is arranged on the z2 side in the z direction of the sealing member 7. More specifically, the obverse-surface wiring 862 is arranged in one of the grooves 74 of the sealing member 7. As shown in FIG. 22, the obverse-surface wiring 862 of the present embodiment has an L shape as viewed in the z direction, and has a portion extending from the connecting portion 861 to the y1 side in the y direction and a portion extending in the x direction. The pad 863 is directly connected to the obverse-surface wiring 862, and is arranged on the z2 side in the z direction of the sealing member 7. More specifically, the pad 863 is arranged in a portion of the groove 74 having the obverse-surface wiring 862 therein, where the portion is located at the end of the groove 74 on the x2 side in the x direction and has a larger width (dimension in the y direction). As viewed in the z direction, the pad 863 has a rectangular shape, and the dimension thereof in the y direction is larger than the width (the dimension in the y direction) of the obverse-surface wiring 862. The pad 863 is a portion to which a bonding wire is bonded when the semiconductor device A10′ is mounted. In the present embodiment, the obverse-surface wiring 862 and the pad 863 are entirely accommodated in the groove 74, and are flush with the obverse surface 71, as in the obverse-surface wiring 812 and the pad 813. Note that the obverse-surface wiring 862 and the pad 863 may protrude from the obverse surface 71 to the z2 side in the z direction, or may be recessed to the z1 side in the z direction. Alternatively, the sealing member 7 may not be formed with the grooves 74, and the obverse-surface wiring 862 and the pad 863 may be arranged on the obverse surface 71.

The conduction path 85 is connected to the third electrode 63 of the semiconductor element 6. The conduction path 85 has a connecting portion 851, an obverse-surface wiring 852, and a pad 853. The connecting portion 851 is accommodated in one of the recessed portions 73 of the sealing member 7, and is in contact with the third electrode 63 of the semiconductor element 6. As shown in FIG. 22, the connecting portion 851 of the present embodiment is accommodated in the recessed portion 73 closest to the y1 side in the y direction out of the four recessed portions 73. The connecting portion 851 is an embedded via, and penetrates the sealing member 7 from the z2 side in the z direction to be connected to the semiconductor element 6. The connecting portion 851 has a tapered shape similar to the connecting portion 811. The connecting portion 851 is not limited to a particular shape.

The obverse-surface wiring 852 is directly connected to the connecting portion 851, and is arranged on the z2 side in the z direction of the sealing member 7. More specifically, the obverse-surface wiring 852 is arranged in one of the grooves 74 of the sealing member 7. As shown in FIG. 22, the obverse-surface wiring 852 of the present embodiment has an L shape as viewed in the z direction, and has a portion extending from the connecting portion 851 to the y1 side in the y direction and a portion extending in the x direction. The pad 853 is directly connected to the obverse-surface wiring 852, and is arranged on the z2 side in the z direction of the sealing member 7. More specifically, the pad 853 is arranged in a portion of the groove 74 having the obverse-surface wiring 852 therein, where the portion is located at the end of the groove 74 on the x2 side in the x direction and has a larger width (dimension in the y direction). As viewed in the z direction, the pad 853 has a rectangular shape, and the dimension thereof in the y direction is larger than the width (the dimension in the y direction) of the obverse-surface wiring 852. The pad 853 is a portion to which a bonding wire is bonded when the semiconductor device A10′ is mounted. In the present embodiment, the obverse-surface wiring 852 and the pad 853 are entirely accommodated in the groove 74, and are flush with the obverse surface 71, as in the obverse-surface wiring 812 and the pad 813. Note that the obverse-surface wiring 852 and the pad 853 may protrude from the obverse surface 71 to the z2 side in the z direction, or may be recessed to the z1 side in the z direction. Alternatively, the sealing member 7 may not be formed with the grooves 74, and the obverse-surface wiring 852 and the pad 853 may be arranged on the obverse surface 71.

The conduction paths 81, 82, 85, and 86 are formed by electroplating, for example, with use of an underlying layer (not illustrated) formed by, for example, sputtering, as a conduction path. Note that the material of the sealing member 7 may be a synthetic resin with an additive containing a metal element that composes an underlying layer, so that when the recessed portions 73 and the grooves 74 are formed by laser irradiation, the metal element contained in the additive in the sealing member 7 is excited to form the underlying layer. The shape and arrangement of each of the conduction paths 81, 82, 85, and 86 are not limited to those described above, and may be designed appropriately depending on the wiring board on which the semiconductor device A10′ is mounted.

In the present embodiment, the constituent material of the conduction path 81 is a first metal. The constituent material of the conduction path 82 is a second metal having a thermoelectric power different from that of the first metal. A thermoelectric power refers to the thermoelectromotive force per 1K produced when a temperature difference is created between opposite ends of an electrically conductive material. In the present embodiment, the second metal is the same as the constituent material of the first electrode 61, which is Cu. In the present embodiment, the first metal is constantan (Cu—Ni alloy: 55Cu-45Ni). The conduction path 82 and the first electrode 61 (Cu) together with the conduction path 81 (constantan) function as a thermocouple. A thermocouple made of Cu and constantan is widely known as a T-type thermocouple. A junction 81a (see FIG. 24) between the connecting portion 811 of the conduction path 81 and the first electrode 61 corresponds to the temperature measuring junction (hot junction) of the thermocouple. The pad 813 of the conduction path 81 and the pad 823 of the conduction path 82 correspond to the reference junctions (cold junctions) of the thermocouple. A voltage is produced between the reference junctions depending on the temperature difference between the reference junctions and the temperature measuring junction. The pad 813 and the pad 823 function as terminals (a first temperature detection terminal and a second temperature detection terminal) that each output a signal for detecting the temperature of the semiconductor element 6. Although not particularly limited, the constituent material of the conduction paths 85 and 86 is Cu in the present embodiment. The conduction path 85 is connected to the third electrode 63 (the gate electrode), and the pad 853 functions as a gate terminal. The conduction path 86 is connected to the first electrode 61 (the source electrode), and the pad 863 functions as a source sense terminal.

The conduction path 83 is connected to the first electrode 61 of the semiconductor element 6. The conduction path 83 is a conductor having a rectangular shape as viewed in the z direction. The conduction path 83 has an exposed surface 83a. The exposed surface 83a faces the z2 side in the z direction, and is exposed from the obverse surface 71 of the sealing member 7. In the present embodiment, the exposed surface 83a is flush with the obverse surface 71. Although not particularly limited, the constituent material of the conduction path 83 is Cu, for example. As with the connecting portion 811 of the conduction path 81 and so on, the conduction path 83 may be formed by electroplating such that the conduction path 83 is accommodated in a recessed portion formed in the sealing member 7. Alternatively, the conduction path 83 may be a plate-like member bonded to the first electrode 61 of the semiconductor element 6. The conduction path 83 is connected to the first electrode 61 (the source electrode), and the exposed surface 83a (the conduction path 83) functions as a source terminal.

The conduction path 84 is connected to the second electrode 62 of the semiconductor element 6. The conduction path 84 is a conductor having a rectangular shape as viewed in the z direction. The conduction path 84 has an exposed surface 84a. The exposed surface 84a faces the z1 side in the z direction, and is exposed from the reverse surface 72 of the sealing member 7. In the present embodiment, the exposed surface 84a is flush with the reverse surface 72. Although not particularly limited, the constituent material of the conduction path 84 is Cu, for example. As with the connecting portion 811 of the conduction path 81 and so on, the conduction path 84 may be formed by electroplating such that the conduction path 84 is accommodated in a recessed portion formed in the sealing member 7. Alternatively, the conduction path 84 may be a plate-like member bonded to the second electrode 62 of the semiconductor element 6. The conduction path 84 is connected to the second electrode 62 (the drain electrode), and the exposed surface 84a (the conduction path 84) functions as a drain terminal.

Next, an example of a semiconductor module B10′ including the semiconductor device A10′ shown in FIGS. 21 to 24 will be described with reference to FIGS. 25 to 29. The semiconductor module B10′ includes a plurality of semiconductor devices A10′, a plurality of semiconductor elements 12, a support member 2, a plurality of terminals 3, a plurality of connecting members 41 to 47, and a resin member 5. The terminals 3 include power terminals 31 and 32, a signal terminal 33, detection terminals 34 and 35, and temperature detection terminals 36 and 37.

FIG. 25 is a perspective view showing the semiconductor module B10′. FIG. 26 is a plan view showing the semiconductor module B10′. For convenience of understanding, FIG. 26 shows the sealing member 5 in phantom, and the outer shape of the sealing member 5 is indicated by an imaginary line (two-dot chain line). FIG. 27 is a partially enlarged view showing a part of FIG. 26. FIG. 28 is a cross-sectional view along line XXVIII-XXVIII in FIG. 26. FIG. 29 is a cross-sectional view along line XXIX-XXIX in FIG. 26. The x, y and z directions shown in FIGS. 25 to 29 correspond to those shown in FIGS. 21 to 24.

As shown in FIGS. 26 and 29, the semiconductor devices A10′ are arranged at equal intervals in the x direction and connected in parallel to each other. In the present embodiment, the semiconductor module B10′ includes five semiconductor devices A10′ as shown in FIG. 26. The number of semiconductor devices A10′ is not limited to this, and can be selected freely according to the performance required for the semiconductor module B10′. Each of the semiconductor devices A10′ is bonded to the support member 2 with a conductive bonding material 110. The conductive bonding material 110 is, for example, solder, silver paste or sintered metal. In each of the semiconductor devices A10′, the reverse surface 72 of the sealing member 7 faces the support member 2. The exposed surface 84a (the drain terminal) of the conduction path 84 is conductively bonded to a portion (a conductor layer 223 of an obverse-surface metal layer 22 described below) of the support member 2 via the conductive bonding material 110. The exposed surface 84a is in contact with the conductive bonding material 110.

The semiconductor elements 12 are, for example, diodes such as Schottky barrier diodes. Each of the semiconductor elements 12 is connected in reverse parallel to a semiconductor device A10′. Each of the semiconductor elements 12 is bonded to the support member 2 with a conductive bonding material 120. The conductive bonding material 120 is, for example, solder, silver paste or sintered metal. The number of semiconductor elements 12 corresponds to the number of semiconductor devices A10′. Note that the semiconductor module B10′ may not include the semiconductor elements 12.

Each of the semiconductor elements 12 has an element obverse surface 12a and an element reverse surface 12b. The element obverse surface 12a and the element reverse surface 12b face away from each other in the z direction. The element obverse surface 12a faces the z2 side in the z direction. The element reverse surface 12b faces the z1 side in the z direction. The element reverse surface 12b faces the support member 2. Each of the semiconductor elements 12 has an anode electrode 121 and a cathode electrode 122. The anode electrode 121 is arranged on the element obverse surface 12a. The cathode electrode 122 is arranged on the element reverse surface 12b. The cathode electrode 122 is electrically connected to a portion (a conductor layer 223 of an obverse-surface metal layer 22 described below) of the support member 2 via a conductive bonding material 120. The cathode electrode 122 is in contact with the conductive bonding material 120.

The support member 2 supports the semiconductor devices A10′ and the semiconductor elements 12, and provides conduction paths between the semiconductor devices A10′ and the terminals 3. The support member 2 includes an insulating substrate 21, an obverse-surface metal layer 22, and a reverse-surface metal layer 23.

The insulating substrate 21 is a flat plate, for example, and is electrically insulative. The constituent material of the insulating substrate 21 is a ceramic material with excellent thermal conductivity, for example, and is aluminum oxide (Al₂O₃) in the present embodiment. The constituent material of the insulating substrate 21 is not limited, and may be other ceramic materials such as aluminum nitride (AlN) or silicon nitride (SiN), for example. The constituent material of the insulating substrate 21 is not limited to a ceramic material, and may be Si or a synthetic resin. The constituent material of the insulating substrate 21 may be any material as long as it has an insulating property and is capable of withstanding the heat generated by the semiconductor devices A10′.

The insulating substrate 21 has an obverse surface 211 and a reverse surface 212. The obverse surface 211 and the reverse surface 212 face away from each other in the z direction. The obverse surface 211 faces the z2 side in the z direction. The reverse surface 212 faces the z1 side in the z direction.

The obverse-surface metal layer 22 is formed on the obverse surface 211 of the insulating substrate 21. The constituent material of the obverse-surface metal layer 22 is a metal such as Cu. The constituent material of the obverse-surface metal layer 22 is not limited. The obverse-surface metal layer 22 is formed by plating, for example. The method for forming the obverse-surface metal layer 22 is not limited. The obverse-surface metal layer 22 is covered with the resin member 5. The obverse-surface metal layer 22 includes conductor layers 221 to 225, a plurality of conductor layers 226, and a plurality of conductor layers 227. The conductor layers 221 to 227 are spaced apart from each other.

The conductor layer 221 includes a strip portion 221a and a terminal bonding portion 221b. The strip portion 221a extends in the x direction, and the connecting members 41 and the connecting member 42 are bonded to the strip portion 221a. The terminal bonding portion 221b is connected to the end of the strip portion 221a on the x2 side in the x direction, and a portion (a pad portion 321 described below) of the power terminal 32 is bonded to the terminal bonding portion 221b.

The conductor layer 222 includes a strip portion 222a and a terminal bonding portion 222b. The strip portion 222a extends in the x direction, and the connecting members 43 are bonded to the strip portion 222a. The terminal bonding portion 222b is connected to the end of the strip portion 222a on the x1 side in the x direction, and a portion (a pad portion 331 described below) of the signal terminal 33 is bonded to the terminal bonding portion 222b.

The conductor layer 223 includes a strip portion 223a and a terminal bonding portion 223b. The strip portion 223a extends in the x direction, and the semiconductor devices A10′ and the semiconductor elements 12 are bonded to the strip portion 223a. The heat from the semiconductor devices A10′ is properly conducted to the strip portion 223a (the conductor layer 223) via the conductive bonding materials 110. The semiconductor devices A10′ bonded to the strip portion 223a are aligned in the direction (x direction) in which the strip portion 223a extends. The terminal bonding portion 223b is connected to the end of the strip portion 223a on the x1 side in the x direction, and a portion (a pad portion 311 described below) of the power terminal 31 is bonded to the terminal bonding portion 223b. As shown in FIGS. 28 and 29, the conductor layer is electrically 223 connected to the conduction path 84 (the drain terminal) of each of the semiconductor devices A10′ via a conductive bonding material 110, and to the cathode electrode 122 of each of the semiconductor elements 12 via a conductive bonding material 120. In other words, the conduction path 84 (the drain terminal) of each of the semiconductor devices A10′ and the cathode electrode 122 of each of the semiconductor elements 12 are electrically connected to each other via the conductor layer 223.

The conductor layer 224 includes a strip portion 224a and a terminal bonding portion 224b. The strip portion 224a extends in the x direction, and the connecting members 44 are bonded to the strip portion 224a. The terminal bonding portion 224b is connected to the end of the strip portion 224a on the x1 side in the x direction, and a portion (a pad portion 351 described below) of the detection terminal 35 is bonded to the terminal bonding portion 224b.

The connecting member 42 is bonded to the conductor layer 225. A portion (a pad portion 341 described below) of the detection terminal 34 is bonded to the conductor layer 225.

The strip portions 221a, 222a, 223a, and 224a of the obverse-surface metal layer 22 are aligned in the y direction and overlap with each other as viewed in the y direction. The order in which the strip portions 221a, 222a, 223a and 224a are arranged in the y direction is not particularly limited. In the present embodiment, the strip portion 224a, the strip portion 222a, the strip portion 221a, and the strip portion 223a are arranged in this order from the y1 side to the y2 side in the y direction, as shown in FIGS. 26 and 27. Thus, the strip portion 221a is located between the strip portion 222a and the strip portion 223a in the y direction, and the strip portion 222a is located between the strip portion 221a and the strip portion 224a in the y direction. The strip portion 223a is located opposite from the strip portion 222a with the strip portion 221a interposed therebetween in the y direction. The conductor layer 225 is arranged on the x1 side in the x direction relative to the terminal bonding portion 222b of the conductor layer 222.

The conductor layers 226 and the conductor layers 227 are arranged on the y2 side in the y direction relative to the strip portion 223a of the conductor layer 223. The obverse-surface metal layer 22 includes the same number of conductor layers 226 and the same number of conductor layers 227 as the number of (five in the present embodiment) semiconductor devices A10′. The conductor layers 226 and the conductor layers 227 are arranged alternately in the × direction. A connecting member 46 is bonded to each of the conductor layers 226. A portion (a pad portion 361 described below) of a temperature detection terminal 36 is bonded to each of the conductor layers 226. A connecting member 47 is bonded to each of the conductor layers 227. A portion (a pad portion 371 described below) of a temperature detection terminal 37 is bonded to each of the conductor layers 227.

The arrangement and shape of each of the conductor layers 221 to 227 are not limited to those described above, and may be designed appropriately depending on, for example, the arrangement of the terminals 3.

The reverse-surface metal layer 23 is formed on the reverse surface 212 of the insulating substrate 21. The constituent material of the reverse-surface metal layer 23 is a metal such as Cu. The constituent material is not particularly limited. The reverse-surface metal layer 23 is formed by electroless plating, for example. The method for forming the reverse-surface metal layer 23 is not limited. As shown in FIGS. 28 and 29, the reverse-surface metal layer 23 has a surface facing the z1 side in the z direction and exposed from the resin member 5. Alternatively, the surface facing the z1 side in the z direction may be covered with the resin member 5. The support member 2 may not include the reverse-surface metal layer 23. In this case, the reverse surface 212 of the insulating substrate 21 may be covered with the resin member 5, or may be exposed from the resin member 5.

Each of the terminals 3 is bonded to the obverse-surface metal layer 22 inside the resin member 5. Each of the terminals 3 protrudes from the insulating substrate 21 as viewed in the z direction. Further, each of the terminals 3 is partially exposed from the resin member 5. The terminals 3 may be formed from the same lead frame. Each of the terminals 3 is made of a metal, and is preferably made of Cu, Ni, a Cu alloy, a Ni alloy, or 42 alloy, for example.

The power terminal 31 is the drain terminal of the semiconductor module B10′. The power terminal 31 is a plate-like member. The power terminal 31 is electrically connected to the conduction path 84 (the drain electrode) of each of the semiconductor devices A10′ via the conductor layer 223 and the conductive bonding materials 110.

The power terminal 31 includes a pad portion 311 and a terminal portion 312. The pad portion 311 is covered with the resin member 5. The pad portion 311 is bonded to the conductor layer 223. The bonding may be performed by any of the methods including bonding with a conductive bonding material (solder, silver paste, sintered metal, etc.), laser bonding, and ultrasonic bonding. The terminal portion 312 is exposed from the resin member 5. As shown in FIG. 26, the terminal portion 312 extends from the resin member 5 to the x1 side in the x direction as viewed in the z direction. The surface of the terminal portion 312 may be plated with silver, for example.

The power terminal 32 is the source terminal of the semiconductor module B10′. The power terminal 32 is a plate-like member. The power terminal 32 is electrically connected to the conduction path 83 (the source terminal) of each of the semiconductor devices A10′ via the conductor layer 221 and the connecting members 41.

The power terminal 32 includes a pad portion 321 and a terminal portion 322. The pad portion 321 is covered with the resin member 5. The pad portion 321 is bonded to the conductor layer 221. The bonding may be performed by any of the methods including bonding with a conductive bonding material, laser bonding, and ultrasonic bonding. The terminal portion 322 is exposed from the resin member 5. As shown in FIG. 26, the terminal portion 322 extends from the resin member 5 to the x2 side in the x direction as viewed in the z direction. The surface of the terminal portion 322 may be plated with silver, for example.

The signal terminal 33 is the gate terminal of the semiconductor module B10′. The signal terminal 33 is electrically connected to the pad 853 (the gate terminal) of the conduction path 85 of each of the semiconductor devices A10′ via the conductor layer 222 and the connecting members 43. The signal terminal 33 receives a drive signal for on/off control of each of the semiconductor devices A10′. The signal terminal 33 is connected to a drive circuit, for example. The drive circuit generates a drive signal for controlling the switching operation of each of the semiconductor devices A10′. The signal terminal 33 receives the drive signal from the drive circuit.

The signal terminal 33 includes a pad portion 331 and a terminal portion 332. The pad portion 331 is covered with the resin member 5. The pad portion 331 is bonded to the conductor layer 222. The bonding may be performed by any of the methods including bonding with a conductive bonding material, laser bonding, and ultrasonic bonding. The terminal portion 332 is exposed from the resin member 5. The terminal portion 332 has an L shape as viewed in the x direction.

The detection terminal 34 is the source sense terminal of the semiconductor module B10′. The detection terminal 34 is electrically connected to the conduction path 83 (the source terminal) of each of the semiconductor devices A10′ via the conductor layer 225, the connecting member 42, the conductor layer 221, and the connecting members 41. The detection terminal 34 is connected to a drive circuit, for example. The voltage applied to the detection terminal 34 is inputted to the drive circuit as a feedback signal.

The detection terminal 34 includes a pad portion 341 and a terminal portion 342. The pad portion 341 is covered with the resin member 5. The pad portion 341 is bonded to the conductor layer 225. The bonding may be performed by any of the methods including bonding with a conductive bonding material, laser bonding, and ultrasonic bonding. The terminal portion 342 is exposed from the resin member 5. The terminal portion 342 has an L shape as viewed in the x direction.

The detection terminal 35 is the source sense terminal of the semiconductor module B10′. The detection terminal 35 is electrically connected to the pad 863 (the source sense terminal) of the conduction path 86 of each semiconductor devices A10′ via the conductor layer 224 and the connecting members 44. A mirror clamp circuit external to the semiconductor module B10′, for example, is connected between the detection terminal 35 and the signal terminal 33. The mirror clamp circuit is a circuit for preventing a malfunction (accidental “ON” of the gate) of each of the semiconductor devices A10′, and includes a MOSFET, for example.

The source terminal of the MOSFET is connected to the detection terminal 35, and the drain terminal of the MOSFET is connected to the signal terminal 33. When a semiconductor device A10′ is turned off, the MOSFET of the mirror clamp circuit is turned on to forcibly make the gate-source voltage of the semiconductor device A10′ approximately 0 (zero) V or a negative bias voltage, thereby suppressing the rise of the gate potential of the semiconductor device A10′.

The detection terminal 35 includes a pad portion 351 and a terminal portion 352. The pad portion 351 is covered with the resin member 5. The pad portion 351 is bonded to the conductor layer 224. The bonding may be performed by any of the methods including bonding with a conductive bonding material, laser bonding, and ultrasonic bonding. The terminal portion 352 is exposed from the resin member 5. As shown in FIG. 28, the terminal portion 352 has an has an L shape as viewed in the x direction.

The detection terminal 34, the signal terminal 33, and the detection terminal 35 are aligned in this order from the x1 side to the x2 side in the x direction as shown in FIGS. 26 and 27, and overlap with each other as viewed in the x direction as shown in FIG. 28. The detection terminal 34, the signal terminal 33, and the detection terminal 35 protrude from a resin side surface 533 on the y1 side in the y direction.

Each of the temperature detection terminals 36 and 37 detects the temperature of a semiconductor device A10′. Each of the semiconductor devices A10′ is provided with one temperature detection terminal 36 and one temperature detection terminal 37. Since the semiconductor module B10′ includes five semiconductor devices A10′ in the present embodiment, five temperature detection terminals 36 and five temperature detection terminals 37 are provided. Each of the temperature detection terminals 36 is bonded to a conductor layer 226. Each of the temperature detection terminals 36 is electrically connected to the pad 813 (the first temperature detection terminal) of the conduction path 81 of a semiconductor device A10′ via a conductor layer 226 and a connecting member 46. Each of the temperature detection terminals 37 is bonded to a conductor layer 227. Each of the temperature detection terminals 37 is electrically connected to the pad 823 (the second temperature detection terminal) of the conduction path 82 of a semiconductor device A10′ via a conductor layer 227 and a connecting member 47.

Each of the temperature detection terminals 36 includes a pad portion 361 and a terminal portion 362. The pad portion 361 is covered with the resin member 5. The pad portion 361 is bonded to a conductor layer 226. The bonding may be performed by any of the methods including bonding with a conductive bonding material, laser bonding, and ultrasonic bonding. The terminal portion 362 is exposed from the resin member 5. The terminal portion 362 has an L shape as viewed in the x direction. Each of the temperature detection terminals 37 includes a pad portion 371 and a terminal portion 372. The pad portion 371 is covered with the resin member 5. The pad portion 371 is bonded to a conductor layer 227. The bonding may be performed by any of the methods including bonding with a conductive bonding material, laser bonding, and ultrasonic bonding. As shown in FIG. 28, the terminal portion 372 is exposed from the resin member 5. The terminal portion 372 has an L shape as viewed in the x direction.

The temperature detection terminals 36 and the temperature detection terminals 37 are alternately arranged in the x direction as shown in FIGS. 26 and 27, and overlap with each other as viewed in the x direction as shown in FIG. 28. The temperature detection terminals 36 and 37 protrude from a resin side surface 534 on the y2 side in the y direction.

Each of the connecting members 41 to 47 electrically connects two separate parts to each other. Each of the connecting members 41 to 47 is a bonding wire. In the present embodiment, the connecting members 41 to 47 are formed by wedge bonding. The connecting members 41 to 47 may be formed by ball bonding. The constituent material of the connecting members 41 to 47 is Al, Au, Cu or an alloy containing one of these, for example, and is not limited. The present embodiment describes the case where the constituent material of the connecting members 41 to 47 is Cu.

Each of the connecting members 41 has a first end bonded to the exposed surface 83a of the conduction path 83 of a semiconductor device A10′, and has a second end bonded to the conductor layer 221. Each of the connecting members 41 electrically connects the conduction path 83 (the source terminal) of a semiconductor device A10′ and the conductor layer 221.

The connecting member 42 has a first end bonded to the conductor layer 221, and has a second end bonded to the conductor layer 225. The connecting member 42 electrically connects the conductor layer 221 and the conductor layer 225. The second end of the connecting member 42 described above may be bonded to the pad portion 341 of the detection terminal 34, instead of being bonded to the conductor layer 225.

Each of the connecting members 43 has a first end bonded to the pad 853 (the gate terminal) of the conduction path 85 of a semiconductor device A10′, and has a second end bonded to the conductor layer 222. Each of the connecting members 43 electrically connects a pad 853 (a gate terminal) and the conductor layer 222.

Each of the connecting members 44 has a first end bonded to the pad 863 (the source sense terminal) of the conduction path 86 of a semiconductor device A11′, and has a second end bonded to the conductor layer 224. Each of the connecting members 44 electrically connects a pad 863 (a source sense terminal) and the conductor layer 224. Each of the connecting members 44 is a sense wire connected to the pad 863 (the source sense terminal) of a semiconductor device A10′ by Kelvin connection.

Each of the connecting members 45 has a first end bonded to the exposed surface 83a of the conduction path 83 of a semiconductor device A10′, and has a second end bonded to the anode electrode 121 of a semiconductor element 12. Each of the connecting members 45 electrically connects the conduction path 83 (the source terminal) of a semiconductor device A10′ and the anode electrode 121 of a semiconductor element 12.

Each of the connecting members 46 has a first end bonded to the pad 813 (the first temperature detection terminal) of the conduction path 81 of a semiconductor device A11′, and has a second end bonded to a conductor layer 226. Each of the connecting members 46 electrically connects a pad 813 (a first temperature detection terminal) and a conductor layer 226. Each of the connecting members 47 has a first end bonded to the pad 823 (the second temperature detection terminal) of the conduction path 82 of a semiconductor device A11′, and has a second end bonded to a conductor layer 227. Each of the connecting members 47 electrically connects a pad 823 (a second temperature detection terminal) and a conductor layer 227.

Note that the constituent material of the connecting members 46 may be the first metal, which is the constituent material of the conduction paths 81, and that the constituent material of the connecting members 47 may be the second metal, which is the constituent material of the conduction paths 82. This facilitates bonding of the connecting members 46 to the pads 813 of the conduction paths 81, and also facilitates bonding of the connecting members 47 to the pads 823 of the conduction paths 82. Further, the junction between a connecting member 46 and a conductor layer 226, and the junction between a connecting member 47 and a conductor layer 227 serve as the reference junctions of a thermocouple. This makes it possible to increase the length of a portion of the thermocouple through which current flows as compared to the case where the pads 813 and 823 are reference junctions, thereby improving the detection accuracy of a temperature.

The resin member 5 is a semiconductor-sealing material that is electrically insulative. The resin member 5 covers the entirety of the semiconductor devices A10′, the semiconductor elements 12, the insulating substrate 21, the obverse-surface metal layer 22, and the connecting members 41 to 47, and covers a portion of each of the terminals 3. The constituent material of the resin member 5 is an epoxy resin, for example. The constituent material of the resin member 5 is not particularly limited. The resin member 5 is formed by transfer molding using a mold, for example. The method for forming the resin member 5 is not particularly limited. As shown in FIGS. 26, 28, and 29, the resin member 5 has a resin obverse surface 51, a resin reverse surface 52, and a plurality of resin side surfaces 531 to 534.

The resin obverse surface 51 and the resin reverse surface 52 face away from each other in the z direction. The resin obverse surface 51 faces the z2 side in the z direction, and the resin reverse surface 52 faces the z1 side in the z direction. The reverse-surface metal layer 23 is exposed from the resin reverse surface 52, and the resin reverse surface 52 and the surface of the reverse-surface metal layer 23 facing the z1 side in the z direction are flush with each other. The resin side surfaces 531 to 534 are connected to and flanked by the resin obverse surface 51 and the resin reverse surface 52. As shown in FIG. 26, the two resin side surfaces 531 and 532 face away from each other in the x direction. The resin side surface 531 is located on the x1 side in the x direction and faces the x1 side in the x direction. The resin side surface 532 is located on the x2 side in the x direction and faces the x2 side in the x direction. The two resin side surfaces 533 and 534 face away from each other in the y direction. The resin side surface 533 is located on the y1 side in the y direction and faces the y1 side in the y direction. The resin side surface 534 is located on the y2 side in the y direction and faces the y2 side in the y direction.

The resin side surfaces 531 to 534 include respective surfaces connected to the resin obverse surface 51 and inclined to become closer to each other as proceeding toward the resin obverse surface 51. In other words, the portion of the resin member 5 that is defined by these inclined surfaces connected to the resin obverse surface 51 has a tapered shape of which sectional area in an x-y plane becomes smaller as proceeding toward the resin obverse surface 51. The resin side surfaces 531 to 534 include respective surfaces connected to the resin reverse surface 52 and inclined to become closer to each other as proceeding toward the resin reverse surface 52. In other words, the portion of the resin member 5 that is defined by these inclined surfaces connected to the resin reverse surface 52 has a tapered shape of which sectional area in an x-y plane becomes smaller as proceeding toward the resin reverse surface 52. The shape of the resin member 5 shown in FIGS. 25 to 29 is one example. The shape of the resin member 5 is not limited to the illustrated shape.

The semiconductor module B10′ is controlled by a drive device attached thereto. The drive device generates a drive signal based on a control signal inputted from the outside and outputs the drive signal to the signal terminal 33. The semiconductor module B10′ drives each of the semiconductor devices A10′ based on the drive signal inputted from the signal terminal 33. The drive device receives voltage from the temperature detection terminals 36 and 37 that make a pair. The voltage belongs to the pad 813 and the pad 823 in the corresponding semiconductor device A10′, and is the voltage between the reference junctions of the thermocouple having the conduction path 81 (constantan) as well as the conduction path 82 and the first electrode 61 (Cu). The voltage corresponds to the temperature difference between the temperature measuring junction and each of the reference junctions. The drive device detects the temperature of the corresponding semiconductor device A10′ based on the voltage, and detects an overheat abnormality. When the detected temperature is equal to or greater than a threshold temperature, the drive device stops outputting a drive signal to terminate the drive of the semiconductor module B10′. Note that the drive device is not limited to a specific configuration.

The following describes advantages of a semiconductor device A10′.

According to the present embodiment, a semiconductor device A10′ includes a conduction path 81 and a conduction path 82 connected to a semiconductor element 6. The constituent material of the conduction path 81 is the first metal. The constituent material of the conduction path 82 is the second metal having a thermoelectric power different from that of the first metal. The constituent material of a first electrode 61 is the same metal as the second metal. The conduction path 82 and the first electrode 61 (Cu) together with the conduction path 81 (constantan) function as a thermocouple, and a junction 81a between a connecting portion 811 of the conduction path 81 and the first electrode 61 is used as a temperature measuring junction of the thermocouple to detect a temperature. The junction 81a is in contact with the semiconductor element 6. With this configuration, the semiconductor device A10′ can detect the temperature of the semiconductor element 6 more accurately than when a temperature detection element, for example, is arranged near the semiconductor device A11′. Further, in the semiconductor device A10′, an element such as a temperature detection element is not formed in an active area of the semiconductor element 6. Thus, the semiconductor device A10′ can provide the entirety of the active area of the semiconductor element 6 for an intended use.

According to the present embodiment, the first metal is constantan, and the second metal is Cu. Thus, the conduction path 82 and the first electrode 61 (Cu) together with the conduction path 81 (constantan) function as a T-type thermocouple.

According to the present embodiment, the semiconductor device A10′ is such that an exposed surface 84a of a conduction path 84 electrically connected to a second electrode 62 (a drain electrode) of the semiconductor element 6 is exposed from a reverse surface 72 of a sealing member 7, and an exposed surface 83a of a conduction path 83 electrically connected to the first electrode 61 (the source electrode) and a pad 853 of a conduction path 85 electrically connected to a third electrode 63 (a gate electrode) are exposed from an obverse surface 71 of the sealing member 7. Thus, the semiconductor device A10′ can be used for a semiconductor module B10′ in the same manner as a conventional semiconductor element. Further, in the semiconductor device A10′, a first temperature detection terminal and a second temperature detection terminal for detecting the temperature of the semiconductor element 6, which comprise a pad 813 of the conduction path 81 and a pad 823 of the conduction path 82, respectively, are exposed from the obverse surface 71 of the sealing member 7. Thus, in the semiconductor module B10′, a conductor layer 226 (227) to which a temperature detection terminal 36 (37) is bonded and the pad 813 (823) can be connected to each other with a connecting member 46 (47).

Although the present embodiment describes the case where the second metal constituting the conduction path 82 is Cu and the first metal constituting the conduction path 81 is constantan, the present disclosure is not limited to this. Any two metals having different thermoelectric powers can be used as the first metal and the second metal. For example, the second metal may be Cu, and the first metal may be Al. Since Cu and Al have the same polarity of thermoelectric power but have different values of thermoelectric power, the conduction path 82 and the first electrode 61 (Cu) together with the conduction path 81 (Al) function as a thermocouple. Further, when the first electrode 61 is made of Al, the conduction path 81 and the first electrode 61 (Al) together with the conduction path 82 (Cu) function as a thermocouple. In this case, the junction between the conduction path 82 and the first electrode 61 corresponds to the temperature measuring junction (hot junction) of the thermocouple. The combination of the first metal and the second metal may be Chromel (registered trademark) (90Ni-10Cr) and Alumel (registered trademark) (94Ni-3Al-1Si-2Mg) as in a K-type thermocouple, Fe and constantan as in a J-type thermocouple, or Chromel and constantan as in an E-type thermocouple. The combination of the first metal and the second metal is not limited to those described above.

Although the present embodiment describes the case where the second metal constituting the conduction path 82 and the metal constituting the first electrode 61 are the same metal (Cu), the present disclosure is not limited to this. The constituent material of the first electrode 61 may be a metal different from the second metal. In this case, however, the difference between the detected temperature and the actual temperature needs to be corrected. For higher accuracy of temperature detection, it is preferable that the constituent material of the first electrode 61 be the same metal as the second metal (or the first metal). If the constituent material of the first electrode 61 is a metal different from each of the first metal and the second metal, a metal plate containing the same metal as the first metal or the second metal may be bonded to the first electrode 61, and the conduction path 81 and the conduction path 82 may be connected to the metal plate. In this case, the metal plate may be a clad material in which a thin plate made of the constituent material of the first electrode 61 is bonded to a surface of a plate made of Cu, and a surface of the thin plate is bonded to the first electrode 61 by, for example, solid-phase diffusion. The configuration of the metal plate and the method for bonding to the first electrode 61 are not limited. For example, the metal plate may be made by forming a layer of the constituent material of the first electrode 61 on a surface of a plate made of Cu by, for example, sputtering.

FIGS. 30 to 37 show a variation of the semiconductor device A10′ according to the first embodiment (the second aspect). In these figures, the elements that are identical with or similar to those of the above embodiment are designated by the same reference numerals as in the above embodiment, and the descriptions thereof are omitted.

### First Variation:

FIG. 30 shows a semiconductor device A11′ according to a first variation of the first embodiment (the second aspect). FIG. 30 is a cross-sectional view showing the semiconductor device A11′, and corresponds to FIG. 24. The semiconductor device A11′ is different from the semiconductor device A10′ in the configuration of the conduction path 81.

In the conduction path 81 of the semiconductor device A11′ according to the present variation, each of the obverse-surface wiring 812 and the pad 813 includes two layers. The obverse-surface wiring 812 includes a first layer 812a and a second layer 812b. The first layer 812a is in contact with a groove 74. The second layer 812b is in contact with the first layer 812a. The pad 813 includes a first layer 813a and a second layer 813b. The first layer 813a is in contact with the groove 74. The second layer 813b is in contact with the first layer 813a. As with the conduction paths 82, 85, and 86, the constituent material of the first layer 812a and the first layer 813a is the second metal (e.g., Cu). As with the connecting portion 811, the constituent material of the second layer 812b and the second layer 813b is the first metal (e.g., constantan). The conduction path 81 is provided by forming the first layer 812a and the first layer 813a with the same material as that of the conduction paths 82, 85, and 86 in the same step as that of forming the conduction paths 82, 85, and 86, and then forming the second layer 812b and the second layer 813b to cover the first layer 812a and the first layer 813a. In the conduction path 81, the first layer 812a and the first layer 813a may be the underlying layers formed as a result of the metal element contained in the additive in the sealing member 7 being excited when the grooves 74 are formed by laser irradiation, and the second layer 812b and the second layer 813b may be formed by electroplating with the underlying layers used as conduction paths.

### Second Variation:

FIG. 31 shows a semiconductor device A12′ according to a second variation of the first embodiment (the second aspect). FIG. 31 is a cross-sectional view showing the semiconductor device A12′, and corresponds to FIG. 24. The semiconductor device A12′ is different from the semiconductor device A10′ in the configuration of the conduction path 81.

In the conduction path 81 of the semiconductor device A12′ according to the present variation, the constituent material of the connecting portion 811 is the same as that of the conduction path 82, which is the second metal (e.g., Cu). In the present variation, a boundary 812c between the connecting portion 811 and the obverse-surface wiring 812 in the conduction path 81 corresponds to the temperature measuring junction (the hot junction) of the thermocouple.

### Third Variation:

FIG. 32 shows a semiconductor device A13′ according to a third variation of the first embodiment (the second aspect). FIG. 32 is a cross-sectional view showing the semiconductor device A13′, and corresponds to FIG. 24. The semiconductor device A13′ is different from the semiconductor device A10′ in the configuration of the conduction path 81.

In the conduction path 81 of the semiconductor device A13′ according to the present variation, the constituent material of the connecting portion 811 and the obverse-surface wiring 812 is the same as that of the conduction path 82, which is the second metal (e.g., Cu). In the present variation, a boundary 813c between the obverse-surface wiring 812 and the pad 813 in the conduction path 81 corresponds to the temperature measuring junction (the hot junction) of the thermocouple.

### Fourth Variation:

FIG. 33 shows a semiconductor device A14′ according to a fourth variation of the first embodiment (the second aspect). FIG. 33 is a cross-sectional view showing the semiconductor device A14′, and corresponds to FIG. 24. The semiconductor device A14′ is different from the semiconductor device A10′ in the configuration of the conduction path 81.

In the conduction path 81 of the semiconductor device A14′ according to the present variation, the constituent material of the connecting portion 811 and the pad 813 is the same as that of the conduction path 82, which is the second metal (e.g., Cu). In the present variation, the boundary 812c between the connecting portion 811 and the obverse-surface wiring 812 in the conduction path 81 corresponds to the temperature measuring junction (the hot junction) of the thermocouple. The pad 823 of the conduction path 82, and the boundary between the pad 813 and the obverse-surface wiring 812 in the conduction path 81 correspond to the reference junctions (cold junctions) of the thermocouple. The present variation facilitates bonding when the material of the bonding wire bonded to the pad 813 is the second metal (e.g., Cu).

### Fifth Variation:

FIG. 34 shows a semiconductor device A15′ according to a fifth variation of the first embodiment (the second aspect). FIG. 34 is a cross-sectional view showing the semiconductor device A15′, and corresponds to FIG. 24. The semiconductor device A15′ is different from the semiconductor device A10′ in the configuration of the conduction path 81.

In the conduction path 81 of the semiconductor device A15′ according to the present variation, the constituent material of the obverse-surface wiring 812 and the pad 813 is the same as that of the conduction path 82, which is the second metal (e.g., Cu). In the present variation, the pad 823 of the conduction path 82, and the boundary between the connecting portion 811 and the obverse-surface wiring 812 in the conduction path 81 correspond to the reference junctions (cold junctions) of the thermocouple. The present variation facilitates bonding when the material of the bonding wire bonded to the pad 813 is the second metal (e.g., Cu).

As can be understood from the second to fifth variations, it is not necessary to form the entirety of the conduction path 81 with the first metal, and only a portion of the conduction path 81 may be formed with the first metal. However, in order to improve the detection accuracy of a temperature by increasing the length of a portion of the thermocouple through which current flows, it is preferable that the entirety of the conduction path 81 be made of the first metal as in the semiconductor device A10′. Suppose that only a portion is made of the first metal. In this case, if it is allowable to increase the dimension of the sealing member 7 in the z direction, the connecting portion 811 may be made of the first metal as in the semiconductor device A15′, and the dimension of the connecting portion 811 in the z direction may be increased. Alternatively, if it is allowable to enlarge the shape of the sealing member 7 as viewed in the z direction, the obverse-surface wiring 812 may be made of the first metal as in the semiconductor device A14′, and the length of the obverse-surface wiring 812 can be increased.

### Sixth Variation:

FIG. 35 shows a semiconductor device A16′ according to a sixth variation of the first embodiment (the second aspect). FIG. 35 is a cross-sectional view showing the semiconductor device A16′, and corresponds to FIG. 24. The semiconductor device A16′ is different from the semiconductor device A10′ in the configuration of the conduction path 81.

The conduction path 81 of the semiconductor device A16′ according to the present variation further includes a metal layer 813d in contact with the pad 813. As with the conduction paths 82, 85, and 86, the constituent material of the metal layer 813d is the second metal (e.g., Cu). The present variation facilitates bonding when the material of a bonding wire to be bonded is the second metal (e.g., Cu).

### Seventh Variation:

FIGS. 36 and 37 show a semiconductor device A17′ according to a seventh variation of the first embodiment (the second aspect). FIG. 36 is a plan view showing the semiconductor device A17′, and corresponds to FIG. 22. For convenience of understanding, FIG. 36 shows the sealing member 7 in phantom, and the outer shape of the sealing member 7 is indicated by an imaginary line (two-dot chain line). FIG. 37 is a cross-sectional view along line XXXVII-XXXVII in FIG. 36, and corresponds to FIG. 24. The semiconductor device A17′ is different from the semiconductor device A10′ in the configuration of each of the conduction paths 81, 82, 85, and 86.

The conduction path 81 of the semiconductor device A17′ according to the present variation includes only the connecting portion 811, and does not include the obverse-surface wiring 812 or the pad 813. The connecting portion 811 has a part exposed from the obverse surface 71 of the sealing member 7, and the part is where a bonding wire is bonded. Similarly, the conduction path 82 (85, 86) includes only the connecting portion 821 (851, 861), and does not include the obverse-surface wiring 822 (852, 862) or the pad 823 (853, 863). The connecting portion 821 (851, 861) has a part exposed from the obverse surface 71 of the sealing member 7, and the part is where a bonding wire is bonded. The semiconductor device A17′ according to the present variation can reduce the dimension in the x direction as compared to the semiconductor device A10′.

The first embodiment (the second aspect) may include any of the components described in the first to seventh variations in any combination.

FIGS. 38 and 39 show other embodiments of the present disclosure. In these figures, the elements that are identical with or similar to those of the above embodiment are designated by the same reference numerals as in the above embodiment, and the descriptions thereof are omitted.

### Second Embodiment (Second Aspect)

FIG. 38 shows a semiconductor device A20′ according to a second embodiment (the second aspect) of the present disclosure. FIG. 38 is a cross-sectional view showing the semiconductor device A20′, and corresponds to FIG. 24. The semiconductor device A20′ according to the present embodiment is different from the semiconductor device A10′ according to the first embodiment (the second aspect) in not including the conduction path 84. The configuration and operation of other components of the present embodiment are the same as those of the first embodiment (the second aspect). Note that the components of the first embodiment (the second aspect) and the variations may be combined in various manners.

The semiconductor device A20′ according to the present embodiment does not include the conduction path 84, and the second electrode 62 of the semiconductor element 6 is exposed from the reverse surface 72 of the sealing member 7.

In the present embodiment, the constituent material of the conduction path 81 is the first metal, and the constituent material of the conduction path 82 is the second metal having a thermoelectric power different from the first metal. The constituent material of the first electrode 61 is the same metal as the second metal. Thus, the conduction path 82 and the first electrode 61 (Cu) together with the conduction path 81 (constantan) function as a thermocouple, and the junction 81a is used as a temperature measuring junction of the thermocouple to detect a temperature. Since the junction 81a is in contact with the semiconductor element 6, the semiconductor device A20′ can detect the temperature of the semiconductor element 6 accurately. Further, the semiconductor device A20′ can provide the entirety of the active area of the semiconductor element 6 for an intended use. In addition, the semiconductor device A20′ has advantages similar to those of the semiconductor device A10′ owing to its common configuration with the semiconductor device A10′. Further, since the semiconductor device A20′ does not include the conduction path 84, the dimension of the semiconductor device A20′ in the z direction can be reduced as compared to that of the semiconductor device A10′ in the z direction.

### Third Embodiment (Second Aspect)

FIG. 39 shows a semiconductor device A30′ according to a third embodiment (the second aspect) of the present disclosure. FIG. 39 is a cross-sectional view showing the semiconductor device A30′, and corresponds to FIG. 24. The semiconductor device A30′ according to the present embodiment is different from the semiconductor device A10′ according to the first embodiment (the second aspect) in that the pad 813 is arranged on the z1 side in the z direction of the sealing member 7. The configuration and operation of other components of the present embodiment are the same as those of the first embodiment (the second aspect). Note that the components of the first and second embodiments and the variations may be combined in various manners.

In the semiconductor device A30′ according to the present embodiment, the sealing member 7 further includes a plurality of through-holes 75 and a plurality of grooves 76. The through-holes 75 penetrate from the obverse surface 71 to the reverse surface 72. Each of the through-holes 75 is connected to a corresponding groove 74. The grooves 76 are recessed from the reverse surface 72 in the z direction. Each of the grooves 76 is connected to a corresponding through-hole 75.

In the semiconductor device A30′, the pad 813 of the conduction path 81 is arranged on the z1 side in the z direction of the sealing member 7. The conduction path 81 further includes a through portion 814 and a reverse-surface wiring 815. The through portion 814 is accommodated in a corresponding through-hole 75 in the sealing member 7, and extends from the obverse surface 71 to the reverse surface 72. The through portion 814 is directly connected to the obverse-surface wiring 812. The reverse-surface wiring 815 is directly connected to the through portion 814, is arranged on the side (the z1 side in the z direction) of the sealing member 7 where the reverse surface 72 is located, and is arranged in a corresponding groove 76 in the sealing member 7. The pad 813 is directly connected to the reverse-surface wiring 815, and is arranged in a portion of the groove 76 having the reverse-surface wiring 815 therein, where the portion is located at the end of the groove 76 on the x2 side in the x direction and has a larger width (dimension in the y direction).

Similarly, the pad 823 (853, 863) of the conduction path 82 (85, 86) is arranged on the z1 side in the z direction of the sealing member 7. The conduction path 82 (85, 86) further includes a through portion 824 (854, 864) and a reverse-surface wiring 825 (855, 865). The through portion 824 (854, 864) is accommodated in a corresponding through-hole 75 in the sealing member 7, and extends from the obverse surface 71 to the reverse surface 72. The through portion 824 (854, 864) is directly connected to the obverse-surface wiring 822 (852, 862). The reverse-surface wiring 825 (855, 865) is directly connected to the through portion 824 (854, 864), is arranged on the side (the z1 side in the z direction) of the sealing member 7 where the reverse surface 72 is located, and is arranged in a corresponding groove 76 in the sealing member 7. The pad 823 (853, 863) is directly connected to the reverse-surface wiring 825 (855, 865), and is arranged in a portion of the groove 76 having the reverse-surface wiring 825 (855, 865) therein, where the portion is located at the end of the groove 76 on the x2 side in the x direction and has a larger width (dimension in the y direction).

In the present embodiment, the constituent material of the conduction path 81 is the first metal, and the constituent material of the conduction path 82 is the second metal having a thermoelectric power different from the first metal. The constituent material of the first electrode 61 is the same metal as the second metal. Thus, the conduction path 82 and the first electrode 61 (Cu) together with the conduction path 81 (constantan) function as a thermocouple, and the junction 81a is used as a temperature measuring junction of the thermocouple to detect a temperature. Since the junction 81a is in contact with the semiconductor element 6, the semiconductor device A30′ can detect the temperature of the semiconductor element 6 accurately. Further, the semiconductor device A30′ can provide the entirety of the active area of the semiconductor element 6 for an intended use. In addition, the semiconductor device A30′ has advantages similar to those of the semiconductor device A10′ owing to its common configuration with the semiconductor device A10′. Further, in the semiconductor device A30′, the pad 813 (823, 853, 863) is arranged on the z1 side in the z direction of the sealing member 7. Thus, the semiconductor device A30′ allows the pad 813 (823, 853, 863) to be directly bonded to the wiring of the wiring board on which the semiconductor device A30′ is mounted. Further, since the conduction path 81 in the semiconductor device A30′ is longer than when the pad 813 is arranged on the z2 side in the z direction of the sealing member 7, the length of the portion of a thermocouple through which current flows is increased. This makes it possible to improve the detection accuracy of a temperature.

A semiconductor module in which any of the semiconductor devices A10′ to A30′ is mounted is not limited to the semiconductor module B10′. The semiconductor devices A10′ to A30′ can be mounted in various semiconductor modules.

FIGS. 40 to 42 show other semiconductor modules on each of which the semiconductor device A10′ is mounted. In these figures, the elements that are identical with or similar to those of the above embodiments are designated by the same reference numerals as in the above embodiments, and the descriptions thereof are omitted.

### First Variation of the Semiconductor Module:

FIGS. 40 and 41 show a semiconductor module B20′ on which the semiconductor device A10′ is mounted. FIG. 40 is a plan view showing the semiconductor module B20′, and corresponds to FIG. 26. For convenience of understanding, FIG. 40 shows the sealing member 5 in phantom, and the outer shape of the sealing member 5 is indicated by an imaginary line (two-dot chain line). FIG. 41 is a cross-sectional view along line XLI-XLI in FIG. 40, and corresponds to FIG. 29. The semiconductor module B20′ according to the present variation is different from the semiconductor module B10′ according to the first embodiment (the second aspect) in that the pad portion 321 of the power terminal 32 is bonded to the exposed surface 83a of the conduction path 83 of each of the semiconductor devices A10′. The configuration and operation of other components of the present variation are the same as those of the first embodiment (the second aspect). Note that the components of the first to third embodiments and the variations may be combined in various manners.

In the semiconductor module B20′ according to the present variation, the obverse-surface metal layer 22 does not include the conductor layer 221. The semiconductor module B20′ does not include the semiconductor elements 12. The orientation of the semiconductor devices A10′ is different from that of the semiconductor devices A10′ in the semiconductor module B10′. Further, the pad portion 321 of the power terminal 32 extends to the x1 side in the x direction, and is bonded to the exposed surface 83a of the conduction path 83 of each of the semiconductor devices A10′. In the semiconductor module B20′ according to the present variation, the obverse-surface metal layer 22 does not need to include the conductor layer 221. This makes it possible to reduce the dimension of the semiconductor module B20′ in the y direction. Further, the semiconductor module B20′ can omit the connecting members 41, since the pad portion 321 of the power terminal 32 is bonded to the exposed surface 83a of the conduction path 83 of each of the semiconductor devices A10′.

### Second Variation of the Semiconductor Module:

FIG. 42 shows a semiconductor module B30′ on which the semiconductor device A10′ is mounted. FIG. 42 is a plan view showing the semiconductor module B30′, and corresponds to FIG. 26. For convenience of understanding, FIG. 42 shows the sealing member 5 in phantom, and the outer shape of the sealing member 5 is indicated by an imaginary line (two-dot chain line). The semiconductor module B30′ according to the present variation is different from the semiconductor module B10′ according to the first embodiment (the second aspect) in the package type. The configuration and operation of other components of the present variation are the same as those of the first embodiment (the second aspect). Note that the components of the first to third embodiments and the variations may be combined in various manners.

The semiconductor module B30′ according to the present variation is provided in a dual flatpack no-leaded (DFN) package. The semiconductor module B30′ includes leads 201 to 205, a semiconductor device A10′, the connecting members 41, 43, 46, and 47, and the resin member 5. The semiconductor device A10′, the connecting members 41, 43, 46, and 47, and the resin member 5 are the same as those in the first embodiment (the second aspect).

The leads 201 to 205 are electrically connected to the semiconductor device A10′. Each of the leads 201 to 205 is made of a metal, and is preferably made of Cu, Ni, a Cu alloy, a Ni alloy, or 42 alloy, for example. The constituent material of each of the leads 201 to 205 is not particularly limited, but is Cu in the present embodiment. The leads 201 to 205 are made of a lead frame formed by stamping a metal plate, for example.

In the semiconductor device A10′, the exposed surface 84a of the conduction path 84 (the drain electrode) is bonded to the lead 201 via the conductive bonding material 110. The connecting member 41 has a first end bonded to the exposed surface 83a of the conduction path 83 of the semiconductor device A10′, and has a second end bonded to the lead 203. The connecting member 41 electrically connects the conduction path 83 and the lead 203. The connecting member 43 has a first end bonded to the pad 853 (the gate terminal) of the conduction path 85 of the semiconductor device A10′, and a second end bonded to the lead 202. The connecting member 43 electrically connects the conduction path 85 and the lead 202.

The connecting member 46 has a first end bonded to the pad 813 (the first temperature detection terminal) of the conduction path 81 of the semiconductor device A10′, and a second end bonded to the lead 205. The connecting member 46 electrically connects the conduction path 81 and the lead 205. The connecting member 47 has a first end bonded to the pad 823 (the second temperature detection terminal) of the conduction path 82 of the semiconductor device A10′, and a second end bonded to the lead 204. The connecting member 47 electrically connects the conduction path 82 and the lead 204. The leads 204 and 205 are the terminals for detecting the temperature of the semiconductor device A10′.

The semiconductor device according to the second aspect of the present disclosure is not limited to the above embodiments. Various design changes can be made to the specific configurations of the elements of the semiconductive device according to the present disclosure. The present disclosure includes the embodiments described in the following clauses.

### Clause 1.

A semiconductor device (A10′) comprising:
a semiconductor element (6);
a sealing member (7) covering the semiconductor element, and including a sealing obverse surface (71) and a sealing reverse surface (72) facing away from each other in a thickness direction; and
a first conduction path (81) and a second conduction path (82) connected to the semiconductor element,
wherein the first conduction path includes a portion containing a first metal, and
the second conduction path includes a portion containing a second metal having a thermoelectric power different from the thermoelectric power of the first metal.

### Clause 2.

The semiconductor device according to clause 1, wherein the first conduction path includes a first connecting portion (811) penetrating through the sealing member from a side where the sealing obverse surface is located, the first connecting portion being connected to the semiconductor element.

### Clause 3.

The semiconductor device according to clause 2, wherein the first connecting portion contains the first metal.

### Clause 4.

The semiconductor device according to clause 2, wherein the first connecting portion does not contain the first metal.

### Clause 5.

The semiconductor device according to any of clauses 2 to 4, wherein the first conduction path includes a first wiring portion (812) connected to the first connecting portion and arranged on the side of the sealing member where the sealing obverse surface is located.

### Clause 6.

The semiconductor device according to clause 5, wherein the first wiring portion contains the first metal.

### Clause 7.

The semiconductor device according to clause 5, wherein the first wiring portion does not contain the first metal.

### Clause 8.

The semiconductor device according to any of clauses 5 to 7, wherein an entirety of the first wiring portion is arranged on the side where the sealing obverse surface is located.

### Clause 9.

The semiconductor device according to any of clauses 5 to 7, wherein the sealing member includes a through-hole (75) penetrating from the sealing obverse surface to the sealing reverse surface, and
the first wiring portion is also arranged in the through-hole and on a side where the sealing reverse surface is located.

### Clause 10.

The semiconductor device according to any of clauses 1 to 9, wherein the first metal is constantan.

### Clause 11.

The semiconductor device according to any of clauses 1 to 10, wherein the second metal is Cu.

### Clause 12.

The semiconductor device according to any of clauses 1 to 11, wherein the semiconductor element includes an element obverse surface (6a) and an element reverse surface (6b) facing away from each other in the thickness direction, a first electrode (61) arranged on the element obverse surface, and a second electrode (62) arranged on the element reverse surface, and
the first conduction path and the second conduction path are connected to the first electrode.

### Clause 13.

The semiconductor device according to clause 12, further comprising a third conduction path (83) connected to the first electrode,
wherein the third conduction path includes a third exposed surface (83a) exposed from the sealing obverse surface, and
the third exposed surface is flush with the sealing obverse surface.

### Clause 14.

The semiconductor device according to clause 12 or 13, further comprising a fourth conduction path (84) connected to the second electrode,
wherein the fourth conduction path includes a fourth exposed surface (84a) exposed from the sealing reverse surface, and
the fourth exposed surface is flush with the sealing reverse surface.

### REFERENCE NUMERALS

<Numerals used in FIGS. 1 to 20>

| | |
|---|---|
| A10, A11, A12, A13, A20, A21, A30: Semiconductor device | |
| 1A: First lead | 1B: Second lead |
| 1C: Third lead | 1D: Fourth lead |
| 1E: Fifth lead | 1F: Sixth lead |
| 111: First pad portion | 111a: Obverse surface |
| 112: First terminal portion | 112a: Terminal end surface |
| 112b: Reverse surface | 113: Bent portion |
| 114a: Connecting end surface | |
| 114b: Reverse-side recessed portion | |
| 121: Second pad portion | 122: Second terminal portion |
| 122a: Terminal end surface | 122b: Reverse surface |
| 123: Bent portion | 124b: Reverse-side recessed portion |
| 131: Die pad (Base) | 131a: First surface |
| 131b: Pad reverse surface | 131c: Through-hole |
| 131d: Mounting surface | 132: Third terminal portion |
| 132a: Terminal end surface | 132b: Reverse surface |
| 133: Intermediate bent portion | 134: Connecting portion |
| 135: Through-hole | 136: Extending portion |
| 137: Engaging portion | 138a: Connecting end surface |
| 138b: Reverse-side recessed portion | 141: Fourth pad portion |
| 141a: Obverse surface | 142: Fourth terminal portion |
| 142a: Terminal end surface | 142b: Reverse surface |
| 151: Fifth pad portion | 152: Fifth terminal portion |
| 153: Bent portion | 161: Sixth pad portion |
| 162: Sixth terminal portion | 2: Semiconductor element |
| 20: Element body | 201: Element obverse surface |
| 202: Element reverse surface | |
| 21: Source electrode (First electrode) | |
| 22: Drain electrode | 23: Gate electrode |
| 24: Source sense electrode | 3: Wire |
| 31: First wire | 32: Second wire |
| 34: Fourth wire | 35: Fifth wire |
| 36: Sixth wire | 4: Sealing resin |
| 41: Resin obverse surface | 42: Resin reverse surface |
| 43, 44, 45, 46: Resin side surface | 47: Recessed portion |
| 48: Resin through-hole | 61: Conductive bonding material |
| x: First direction | y: Second direction |
| z: Thickness direction | |

<Numerals used in FIGS. 21 to 42>
A10′-A17′, A20′, A30′: Semiconductor device
6: Semiconductor element
6a: Element obverse surface
6b: Element reverse surface
61: First electrode
62: Second electrode
63: Third electrode
7: Sealing member
71: Obverse surface
72: Reverse surface
73: Recessed portion
74: Groove
75: Through-hole
76: Groove
81: Conduction path
81a: Junction
811: Connecting portion
812: Obverse-surface wiring
812a: First layer
812b: Second layer
812c: Boundary
813: Pad
813a: First layer
813b: Second layer
813c: Boundary
813d: Metal layer
814: Through portion
815: Reverse-surface wiring
82: Conduction path
821: Connecting portion
822: Obverse-surface wiring
823: Pad
824: Through portion
825: Reverse-surface wiring
85: Conduction path
851: Connecting portion
852: Obverse-surface wiring
853: Pad
854: Through portion
855: Reverse-surface wiring
86: Conduction path
861: Connecting portion
862: Obverse-surface wiring
863: Pad
864: Through portion
865: Reverse-surface wiring
83: Conduction path
83a: Exposed surface
84: Conduction path
84a: Exposed surface
B10′, B20′, B30′: Semiconductor module
12: Semiconductor element
12a: Element obverse surface
12b: Element reverse surface
121: Anode electrode
122: Cathode electrode
110, 120: Conductive bonding material
2: Support member
21: Insulating substrate
211: Obverse surface
212: Reverse surface
22: Obverse-surface metal layer
221, 222, 223, 224, 225, 226, 227: Conductor layer
221a, 222a, 223a, 224a: Strip portion
221b, 222b, 223b, 224b: Terminal bonding portion
23: Reverse-surface metal layer
201-205: Lead
3: Terminal
31, 32: Power terminal
33: Signal terminal
34, 35: Detection terminal
36, 37: Temperature detection terminal
311, 321, 331, 341, 351, 361, 371: Pad portion
312, 322, 332, 342, 352, 362, 372: Terminal portion
41-47: Connecting member
5: Resin member
51: Resin obverse surface
52: Resin reverse surface
531, 532, 533, 534: Resin side surface

1. A semiconductor device comprising:
a first lead, a second lead, and a third lead including a base that includes a first surface facing a first side in a thickness direction;
a semiconductor element mounted on the first surface;
a plurality of wires each having one end connected to the semiconductor element; and
a sealing resin covering the semiconductor element, and a portion of each of the first lead, the second lead, and the third lead, and the plurality of wires,
wherein the first lead includes a first pad portion, and a first terminal portion connected to the first pad portion and used for measuring a temperature,
the second lead includes a second pad portion, and a second terminal portion connected to the second pad portion and used for measuring a temperature,
the third lead includes a third terminal portion connected to the base,
the semiconductor element includes an element obverse surface facing the first side in the thickness direction and a first electrode arranged on the element obverse surface,
the plurality of wires include a first wire and a second wire that are made of metals having different thermoelectric powers,
the first wire is connected to the first electrode and the first pad portion, and
the second wire is connected to the first electrode and the second pad portion.

2. The semiconductor device according to claim 1, further comprising a fourth lead including a fourth pad portion and a fourth terminal portion connected to the fourth pad portion,
wherein the plurality of wires include a fourth wire connected to the semiconductor element and the fourth pad portion, and
each of the first terminal portion, the second terminal portion, the third terminal portion, and the fourth terminal portion is arranged on a first side or a second side in a first direction perpendicular to the thickness direction relative to the base.

3. The semiconductor device according to claim 2, wherein the first terminal portion, the second terminal portion, the third terminal portion, and the fourth terminal portion extend to the first side in the first direction relative to the base, and are spaced apart from each other in a second direction perpendicular to the thickness direction and the first direction, and
one of the first terminal portion and the second terminal portion is located at an outermost position in the second direction.

4. The semiconductor device according to claim 3, wherein the first terminal portion and the second terminal portion are adjacent to each other in the second direction.

5. The semiconductor device according to claim 3, wherein the first pad portion, the second pad portion, and the fourth pad portion are arranged at an end of the first lead, an end of the second lead, and an end of the fourth lead on the second side in the first direction, respectively, and
the first pad portion and the second pad portion are offset from the fourth pad portion to the first side in the first direction.

6. The semiconductor device according to claim 3, wherein the semiconductor element is a switching element including a drain electrode, a gate electrode, and a source electrode.

7. The semiconductor device according to claim 6, wherein the first electrode is the source electrode.

8. The semiconductor device according to claim 7, wherein the semiconductor element includes an element reverse surface facing a second side in the thickness direction,
the gate electrode is arranged on the element obverse surface, and
the drain electrode is arranged on the element reverse surface.

9. The semiconductor device according to claim 8, further comprising a fifth lead including a fifth pad portion and a fifth terminal portion connected to the fifth pad portion,
wherein the plurality of wires include a fifth wire,
the third terminal portion is electrically connected to the drain electrode,
the fourth wire is connected to the gate electrode and the fourth pad portion, and
the fifth wire is connected to the source electrode and the fifth pad portion.

10. The semiconductor device according to claim 8, wherein the plurality of wires include a fifth wire,
the third terminal portion is electrically connected to the drain electrode,
the fourth wire is connected to the gate electrode and the fourth pad portion, and
the fifth wire is connected to the source electrode and the first pad portion.

11. The semiconductor device according to claim 2, wherein the semiconductor element is a switching element including a drain electrode, a gate electrode, and a source electrode,
the semiconductor element includes an element reverse surface facing a second side in the thickness direction,
the first electrode is the source electrode,
the gate electrode is arranged on the element obverse surface,
the drain electrode is arranged on the element reverse surface,
the base includes a mounting surface facing the second side in the thickness direction and exposed from the sealing resin,
the third terminal portion is electrically connected to the drain electrode,
the first terminal portion, the second terminal portion, and the fourth terminal portion extend to the first side in the first direction relative to the base, and are spaced apart from each other in a second direction perpendicular to the thickness direction and the first direction,
the third terminal portion is arranged on the second side in the first direction relative to the base, and
one of the first terminal portion and the second terminal portion is located at an outermost position in the second direction.

12. The semiconductor device according to claim 11, further comprising a fifth lead including a fifth pad portion and a fifth terminal portion connected to the fifth pad portion,
wherein the plurality of wires include a fifth wire,
the fifth terminal portion is arranged on the first side in the first direction relative to the base, and is spaced apart from the first terminal portion, the second terminal portion, and the fourth terminal portion in the second direction,
the fourth wire is connected to the gate electrode and the fourth pad portion, and
the fifth wire is connected to the source electrode and the fifth pad portion.

13. The semiconductor device according to claim 11, wherein the plurality of wires include a fifth wire,
the fourth wire is connected to the gate electrode and the fourth pad portion, and
the fifth wire is connected to the source electrode and the first pad portion.

14. The semiconductor device according to claim 1, wherein the first wire and the first electrode are made of a same metal material.

15. The semiconductor device according to claim 1, wherein the first wire and the first lead are made of a same metal material, and the second wire and the second lead are made of a same metal material.
